(19) United States
(12) Patent Application Publication
(10) Pub. No.: US 2017/0133163 A1
(43) Pub. Date: May 11, 2017

(54) PEROVSKITE-CONTAINING SOLAR CELLS COMPRISING FULLEROPYRROLIDINE INTERLAYERS

(71) Applicant: The University of Massachusetts, Boston, MA (US)

(72) Inventors: Thomas P. Russell, Amherst, MA (US); Todd Emrick, South Deerfield, MA (US); Yao Liu, Amherst, MA (US); Zachariah A. Page, Goleta, CA (US)

(21) Appl. No.: 15/335,918

(22) Filed: Oct. 27, 2016

Related U.S. Application Data
(60) Provisional application No. 62/252,026, filed on Nov. 6, 2015.
(60) Provisional application No. 62/255,055, filed on Nov. 13, 2015.

(51) Int. Cl. H01G 9/20; H01L 51/00; H01L 51/42

(52) U.S. Cl. CPC H01G 9/2072; H01L 51/4226; H01G 9/2031; H01L 51/0047; H01L 51/0077; H01L 51/0037; H01L 51/0035; H01L 51/0036

(57) ABSTRACT

Perovskite-containing solar cells are described herein. An inverted perovskite solar includes an anode substrate, a photoactive layer including a perovskite, a hole transport layer disposed between the anode substrate and the photoactive layer, an electron transport layer, a metal cathode layer, and an interlayer disposed between the electron transport layer and the metal cathode layer. A tandem solar cell includes a first sub-cell, a second sub-cell, and an interconnecting layer disposed between the first sub-cell and the second sub-cell. The first sub cell includes a perovskite layer having a thickness of 50 to 200 nanometers. The second sub-cell includes a photoactive layer and an interlayer disposed on the photoactive layer. The interlayers and the interconnecting layer each include a fullerpyrrolidine having a structure as defined herein.

### STATEMENT REGARDING FEDERALLY SPONSORED RESEARCH & DEVELOPMENT

This invention was made with government support under the Energy Frontier Research Center at the University of Massachusetts (DE-SC0001087) awarded by the Department of Energy, and grant no. DMR-0820506 awarded by the U.S. National Science Foundation. The government has certain rights in the invention.

### BACKGROUND

Perovskite solar cells have attracted extensive attention. See, e.g., H.-S. Kim, C.-R. Lee, J.-H. Im, K.-B. Lee, T. Moehl, A. Marchioro, S.-J. Moon, R. Humphry-Baker, J.-H. Yum, J. E. Moser, M. Gratzel, N.-G. Park, Sci. Rep. 2012, 2, 591: M. M. Lee, J. Teuscher, T. Miyasaka, T. N. Murakami, H. J. Snaith, Science 2012, 338, 643; N. J. Jeon, H. G. Lee, Y. C. Kim, J. Seo, J. H. Noh, J. Lee, S. I. Seok, J. Am. Chem. Soc. 2014, 136, 7837; J.-W. Lee, D.-J. Seol, A.-N. Cho, N.-G. Park, Adv. Mater. 2014, 26, 4991; C.-H. Chiang, Z.-L. Tseng, C.-G. Wu, J. Mater. Chem. A 2014, 2, 15897; N. J. Jeon, J. H. Noh, Y. C. Kim, W. S. Yang, S. Ryu, S. I. Seok, Nat. Mater. 2014, 13, 897; Z. Xiao, C. Bi, Y. Shao, Q. Dong, Q. Wang, Y. Yuan, C. Wang, Y. Gao, J. Huang, Energy Environ. Sci. 2014, 7, 2619. This emerging photovoltaic technology has been regarded as a promising path to cost-effective solar cells. See, e.g., P. Docampo, S. Guldin, T. Leijtens, N. K. Noel, U. Steiner, H. J. Snaith, Adv. Mater. 2014, 26, 4013; M. A. Green, A. Ho-Baillie, H. J. Snaith, Nat. Photon. 2014, 8, 506; P. Gao, M. Gratzel, M. K. Nazeeruddin, Energy Environ. Sci. 2014, 7, 2448; S. Kazim, M. K. Nazeeruddin, M. Grätzel, S. Ahmad, Angew. Chem. Int. Edit. 2014, 53, 2812; J. Burschka, N. Pellet, S.-J. Moon, R. Humphry-Baker, P. Gao, M. K. Nazeeruddin, M. Gratzel, Nature 2013, 499, 316; M. Liu, M. B. Johnston, H. J. Snaith, Nature 2013, 501, 395; D. Liu, T. L. Kelly, Nat. Photon. 2014, 8, 133; M. Xiao, F. Huang, W. Huang, Y. Dkhissi, Y. Zhu, J. Etheridge, A. Gray-Weale, U. Bach, Y.-B. Cheng, L. Spiccia, Angew. Chem. Int. Edit. 2014, 53, 9898; Z. Xiao, Q. Dong, C. Bi, Y. Shao, Y. Yuan, J. Huang, Adv. Mater. 2014, 26, 6503; Y. Wu, A. Islam, X. Yang, C. Qin, J. Liu, K. Zhang, W. Peng, L. Han, Energy Environ. Sci. 2014, 7, 2934; H. S. Jung, N.-G. Park, Small 2014, 11, 10; P. P. Boix, K. Nonomura, N. Mathews, S. G. Mhaisalkar, Mater. Today 2014, 17, 16. Typically, perovskite solar cells are fabricated with a mesoscopic or planar heterojunction active layer. In mesoscopic devices, perovskite is deposited onto a microporous scaffold (e.g. titanium dioxide (TiO₂), zinc oxide (ZnO), aluminum oxide (Al₂O₃)). Planar heterojunctions have a perovskite active layer sandwiched between charge selective transport layers. See, e.g., H. J. Snaith, J. Phys. Chem. Lett. 2013, 4, 3623. Due to the high absorption coefficient (see, e.g., C. C. Stoumpos, C. D. Malliakas, M. G. Kanatzidis, Inorg. Chem. 2013, 52, 9019), low exciton binding energy (see, e.g., H. J. Snaith, J. Phys. Chem. Lett. 2013, 4, 3623; C. C. Stoumpos, C. D. Malliakas, M. G. Kanatzidis, Inorg. Chem. 2013, 52, 9019), and long carrier-diffusion length (see, e.g., H. J. Snaith, J. Phys. Chem. Lett. 2013, 4, 3623; C. C. Stoumpos, C. D. Malliakas, M. G. Kanatzidis, Inorg. Chem. 2013, 52, 9019, F. Hao, C. C. Stoumpos, R. P. H. Chang, M. G. Kanatzidis, J. Am. Chem. Soc. 2014, 136, 8094), metal halide perovskites with organic counterions have enabled both mesoscopic and planar solar cells to achieve power conversion efficiencies (PCEs) greater than 18% (see, e.g., W. Nie, H. Tsai, R. Asadpour, J.-C. Blancon, A. J. Neukirch, G. Gupta, J. J. Crochet, M. Chhowalla, S. Tretiak, M. A. Alam, H.-L. Wang, A. D. Mohite, Science 2015, 347, 522; J. H. Heo, H. J. Han, D. Kim, T. K. Ahn, S. H. Im, Energy Environ. Sci. 2015, 8, 1602; H. Zhou, Q. Chen, G. Li, S. Luo, T.-b. Song. H.-S. Duan, Z. Hong, J. You, Y. Liu, Y. Yang, Science 2014, 345, 542; W. S. Yang, J. H. Noh, N. J. Jeon, Y. C. Kim, S. Ryu, J. Seo, S. I. Seok, Science 2015, 348, 1234; N. Ahn, D.-Y. Son, I.-H. Jang, S. M. Kang, M. Choi, N.-G. Park, J. Am. Chem. Soc. 2015, 137, 8696; C.-G. Wu, C.-H. Chiang, Z.-L. Tseng, M. K. Nazeeruddin, A. Hagfeldt, M. Gratzel, Energy Environ. Sci. 2015, 10.1039/C5EE00645G), with state-of-the-art mesoscopic devices reaching certified PCEs of 20.1% (see, e.g., W. S. Yang, J. H. Noh, N. J. Jeon, Y. C. Kim, S. Ryu, J. Seo, S. I. Seok, Science 2015, 348, 1234).

To date, perovskite solar cells with planar heterojunction structures are slightly less efficient than their mesoscopic counterparts, but their fabrication is straightforward and compatible with well-established solution-based low temperature fabrication roll-to-roll procedures used for the production of polymer solar cells. See, e.g., W. Nie, H. Tsai, R. Asadpour, J.-C. Blancon, A. J. Neukirch, G. Gupta, J. J. Crochet, M. Chhowalla, S. Tretiak, M. A. Alam, H.-L. Wang, A. D. Mohite, Science 2015, 347, 522; J. H. Heo, H. J. Han, D. Kim, T. K. Ahn, S. H. Im, Energy Environ. Sci. 2015, 8, 1602; H. Zhou, Q. Chen, G. Li, S. Luo, T.-b. Song, H.-S. Duan, Z. Hong, J. You, Y. Liu, Y. Yang, Science 2014, 345, 542; W. S. Yang, J. H. Noh, N. J. Jeon, Y. C. Kim, S. Ryu, J. Seo, S. I. Seok, Science 2015, 348, 1234.

The incorporation of charge selective transport layers at the electrode/active layer junctions has often been regarded as a prerequisite to realize efficient charge extraction in planar perovskite solar cells. See, e.g., Y. Zhang, M. Liu, G. E. Eperon, T. C. Leijtens, D. McMeekin, M. Saliba, W. Zhang, M. de Bastiani, A. Petrozza, L. M. Herz, M. B. Johnston, H. Lin, H. J. Snaith, Mater. Horiz. 2015, 2, 315. Thus, great effort has been focused on the development and understanding of interfacial engineering between perovskite and electron transport layers (ETLs) or hole transport layers (HTLs) for effective charge carrier separation. See, e.g., K.-G. Lim, H.-B. Kim, J. Jeong, H. Kim, J. Y. Kim, T.-W. Lee, Adv. Mater. 2014, 26, 6461; J.-Y. Jeng, K.-C. Chen, T.-Y. Chiang, P.-Y. Lin, T.-D. Tsai, Y.-C. Chang, T.-F. Guo, P. Chen, T.-C. Wen, Y.-J. Hsu, Adv. MAater. 2014, 26, 4107; B. Conings, L. Baeten, C. De Dobbelaere, J. D'Haen, J. Manca, H.-G. Boyen, Adv. Mater. 2014, 26, 2041; S. N. Habisreutinger, T. Leijtens, G. E. Eperon, S. D. Stranks, R. J. Nicholas, H. J. Snaith, Nano Lett. 2014, 14, 5561; E. Edri, S. Kirmayer, S. Mukhopadhyay, K. Gartsman, G. Hodes, D. Cahen, Nat. Commun. 2014, 5, 3461. In perovskite solar cells, the diffusion length of electrons is shorter than holes and it is regarded as a major limitation associated with these devices. See, e.g., K. Wang, C. Liu, P. Du, J. Zheng, X. Gong, Energy Environ. Sci. 2015, 8, 1245; C. S. Ponseca, T. J. Savenije, M. Abdellah, K. Zheng, A. Yartsev, T. Pascher, T. Harlang, P. Chabera, T. Pullerits, A. Stepanov, J.-P. Wolf, V. Sundstrom, J. Am. Chem. Soc. 2014, 136, 5189. To address this limitation, compact semiconducting metal oxide (e.g. ZnO, TiO₂) ETLs have been used to facilitate electron transport in planar heterojunction devices. See, e.g., M. M. Lee, J. Teuscher, T. Miyasaka, T. N. Murakami, H. J. Snaith, Science 2012, 338, 643; D. Liu, T. L. Kelly, Nat. Photon. 2014, 8, 133; A. K. Chandiran, A. Yella, M. T. Mayer, P. Gao, M. K. Nazeeruddin, M. Gratzel, Adv. Mater. 2014, 26, 4309; J. H. Heo, S. H. Im, J. H. Noh, T. N. Mandal, C.-S. Lim, J. A. Chang, Y. H. Lee, H.-j. Kim, A. Sarkar, K. NazeeruddinMd, M. Gratzel, S. I. Seok, Nat. Photon. 2013, 7, 486. In addition to the use of metal oxide layers, electrode work function modification by an interlayer can further improve the performance of perovskite solar cells. See, e.g., H. Zhou, Q. Chen, G. Li, S. Luo, T.-b. Song, H.-S. Duan, Z. Hong, J. You, Y. Liu, Y. Yang, Science 2014, 345, 542; L. Zuo, Z. Gu, T. Ye, W. Fu, G. Wu, H. Li, H. Chen, J. Am. Chem. Soc. 2015, 137, 2674; P.-W. Liang, C.-C. Chueh, X.-K. Xin, F. Zuo, S. T. Williams, C.-Y. Liao, A. K. Y. Jen, Adv. Energy Mater. 2015, 5, 1400960; C.-C. Chueh, C.-Z. Li, A. K. Y. Jen, Energy Environ. Sci. 2015, 8, 1160; H. Azimi, T. Ameri, H. Zhang, Y. Hou, C. O. R. Quiroz, J. Min, M. Hu, Z.-G. Zhang, T. Przybilla, G. J. Matt, E. Spiecker, Y. Li, C. J. Brabec, Adv. Energy Mater. 2015, 5, 1401692; H. Zhang, H. Azimi, Y. Hou, T. Ameri, T. Przybilla, E. Spiecker, M. Kraft, U. Scherf, C. J. Brabec, Chem. Mater. 2014, 26, 5190; Q. Xue, Z. Hu, J. Liu, J. Lin, C. Sun, Z. Chen, C. Duan, J. Wang, C. Liao, W. M. Lau, F. Huang, H.-L. Yip, Y. Cao, J. Mater. Chem. A 2014, 2, 19598; J. Seo, S. Park, Y. Chan Kim, N. J. Jeon, J. H. Noh, S. C. Yoon, S. I. Seok, Energy Environ. Sci. 2014, 7, 2642; P.-W. Liang, C.-Y. Liao, C.-C. Chueh, F. Zuo, S. T. Williams, X.-K. Xin, J. Lin, A. K. Y. Jen, Adv. Mater. 2014, 26, 3748. For example, Yang et al. incorporated polyethyleneimine ethoxylated (PEIE) between an indium tin oxide (ITO) electrode and TiO₂ to significantly increase the PCE of planar heterojunction perovskite solar cells, identifying that reduction of ITO's work function (Φ) by PEIE, due to the presence of a negative interfacial dipole, was a leading contributor to the observed device improvement. See, e.g., H. Zhou, Q. Chen, G. Li, S. Luo, T.-b. Song, H.-S. Duan, Z. Hong, J. You, Y. Liu, Y. Yang, Science 2014, 345, 542. Phenyl-C₆₁-butyric acid methyl ester (PC₆₁BM) has been used as an alternative ETL to metal oxide layers in planar heterojunction devices, providing more efficient charge injection from perovskite (see, e.g., J. H. Heo, H. J. Han, D. Kim, T. K. Ahn, S. H. Im, Energy Environ. Sci. 2015, 8, 1602), while allowing for low-temperature solution processing that precludes ITO's use as an electron extracting electrode. See, e.g., J. H. Heo, H. J. Han, D. Kim, T. K. Ahn, S. H. Im, Energy Environ. Sci. 2015, 8, 1602; J.-Y. Jeng, Y.-F. Chiang, M.-H. Lee, S.-R. Peng, T.-F. Guo, P. Chen, T.-C. Wen, Adv. Mater. 2013, 25, 3727; C. Kuang, G. Tang, T. Jiu, H. Yang, H. Liu, B. Li, W. Luo, X. Li, W. Zhang, F. Lu, J. Fang, Y. Li, Nano Lett. 2015, 15, 2756. However, utilizing ITO as a hole extracting electrode in perovskite-based solar cells (described in the literature as inverted devices) has only been studied since 2013 (see, e.g., J.-Y. Jeng, Y.-F. Chiang, M.-H. Lee, S.-R. Peng, T.-F. Guo, P. Chen, T.-C. Wen, Adv. Mater. 2013, 25, 3727), where the function of the interface between metal electrode and PC₆₁BM in these devices is generally not well understood.

Interface modification layers can lower the electrode Φ due to the presence of a negative interfacial dipole, causing an increase in the electrostatic potential across the device. See, e.g., Z. A. Page, V. V. Duzhko, T. Emrick, Macromolecules 2013, 46, 344. The strengthened electric field increases free charge generation and extraction efficiency to enhance the short-circuit current density (J_{SC}) and fill factor (FF). The interfacial dipole moreover increases the Φ offset between the two electrodes of the device, thus maximizing open-circuit voltage (V_{OC}). See, e.g., Z. A. Page, Y. Liu, V. V. Duzhko, T. P. Russell, T. Emrick, Science 2014, 346, 441; Y. Liu, Z. A. Page, S. Ferdous, F. Liu, P. Kim, T. Emrick, T. P. Russell, Adv. Energy Mater. 2015, 5, 1500405. However, the influence of interface modification on electronic transport and recombination kinetics in perovskite solar cells has not been fully investigated, though it is critical to understand interface engineering to further enhance device performance.

Additionally, in pursuit of better device performance, tandem solar cells containing perovskites have also emerged and attracted extensive attention as an alternative device architecture. See, e.g., C. D. Bailie, M. G. Christoforo, J. P. Mailoa, A. R. Bowring, E. L. Unger, W. H. Nguyen, J. Burschka, N. Pellet, J. Z. Lee, M. Gratzel, R. Noufi, T. Buonassisi, A. Salleo, M. D. McGehee, Energy Environ. Sci. 2015, 8, 956; M. A. Green, T. Bein, Nat. Mater. 2015, 14, 559; J. P. Mailoa, C. D. Bailie, E. C. Johlin, E. T. Hoke, A. J. Akey, W. H. Nguyen, M. D. McGehee, T. Buonassisi, Appl. Phys. Lett. 2015, 106, 121105; H. Uzu, M. Ichikawa, M. Hino, K. Nakano, T. Meguro, J. L. Hernandez, H.-S. Kim, N.-G. Park, K. Yamamoto, Appl. Phys. Lett. 2015, 106, 013506; Y. Yang, Q. Chen, Y.-T. Hsieh, T.-B. Song, N. D. Marco, H. Zhou, Y. Yang, ACS Nano 2015, 9, 7714; C.-C. Chen, S.-H. Bae, W.-H. Chang, Z. Hong, G. Li, Q. Chen, H. Zhou, Y. Yang, Mater. Horiz. 2015, 2, 203. In particular, polymer solar cells, which are easily processed from solution and provide an avenue towards flexible devices, are promising candidates to integrate with planar heterojunction perovskite solar cells to yield tandem devices amenable to low temperature roll-to-roll fabrication. See, e.g., C.-C. Chen, S.-H. Bae, W.-H. Chang, Z. Hong, G. Li, Q. Chen, H. Zhou, Y. Yang, Mater. Horiz. 2015, 2, 203; T.-B. Song, Q. Chen, H. Zhou, C. Jiang, H.-H. Wang, Y. Yang, Y. Liu, J. You, Y. Yang, J. Mater. Chem. A 2015, 3, 9032.

Only one polymer/perovskite hybrid tandem solar cell has been reported to date with a maximum PCE of 10.2%, where the front sub-cell comprises polymer and the back sub-cell comprises perovskite. Considering the state-of-the-art for both perovskite and polymer single junction devices, tremendous efforts are required to optimize tandem perovskite/polymer solar cells. Thus far, the preparation of perovskite/polymer tandem solar cells has been hindered by two factors: the thermal/chemical treatment used during perovskite fabrication and thick perovskite active layers (i.e., greater than 200 nanometers (nm)) generated from standard crystallization methodologies. The thermal annealing or chemical bath treatments are not compatible with most polymer-based active layers, eliminating the use of a polymer front sub-cell, while thick perovskite active layers prevent light from reaching a back sub-cell. Recently, ultra-thin, semitransparent perovskite films were prepared with an efficiency approaching 10% (see, e.g., E. D. Gaspera, Y. Peng, Q. Hou, L. Spiccia, U. Bach, J. J. Jasieniak, Y.-B. Cheng, Nano Energy, 2015, 13, 249; C.-Y. Chang, K.-T. Lee, W.-K. Huang, H.-Y. Siao, Y.-C. Chang, Chem. Mater., 2015, 27, 5122; Y. Zhou, M. Yang, W. Wu, A. L. Vasiliev, K. Zhu, N. P. Padture, J. Mater. Chem. A, 2015, 3, 8178), representing a channel towards tandem solar cells with a thin perovskite active layer comprising the front sub-cell. Although tin perovskites have been identified as more environmentally harmful compared to lead-based perovskites, (see, e.g., L. Serrano-Lujan, N. Espinosa, T. T. Larsen-Olsen, J. Abad, A. Urbina, F. C. Krebs, Adv. Energy Mater 2015, 5, 1501119) a reduction in the amount of lead within a perovskite-containing solar cell (e.g., thinner active layer) only serves to further alleviate the potential environmental impact. However, reducing the thickness of perovskite comes at the cost of reduced absorption of visible light, resulting in an overall lower efficiency than their thicker counterparts.

Accordingly, there is a continuing need for improved perovskite solar cells that can overcome the above-described technical limitations.

### BRIEF SUMMARY

One embodiment is an inverted perovskite solar cell comprising an anode substrate; a photoactive layer comprising a perovskite; a hole transport layer disposed between the anode substrate and the photoactive layer; an electron transport layer disposed on the photoactive layer; a metal cathode layer; and an interlayer disposed between the electron transport layer and the metal cathode layer, wherein the interlayer comprises a fulleropyrrolidine having structure (I)

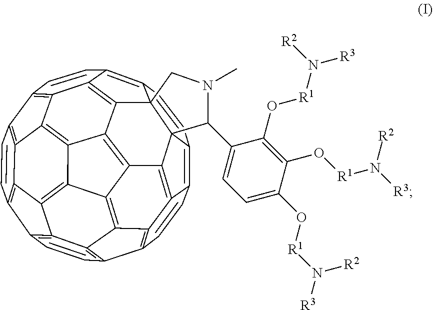

wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group.

Another embodiment is an inverted perovskite solar cell comprising an anode substrate comprising indium tin oxide; a photoactive layer comprising a perovskite; a hole transport layer disposed between the anode substrate and the photoactive layer; an electron transport layer comprising fullerene or a derivative thereof disposed on the photoactive layer; a metal cathode layer comprising silver; and an interlayer disposed between the electron transport layer and the metal cathode layer, wherein the interlayer comprises a fulleropyrrolidine having structure (IV)

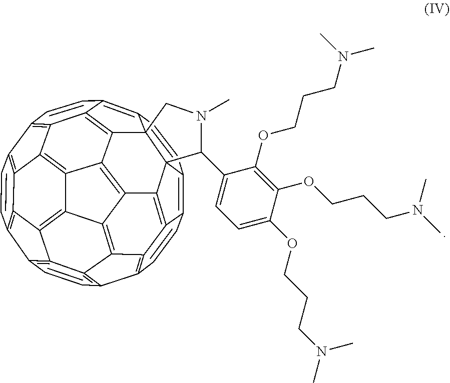 [SMILES: CN(C)CCCOc1ccc(C2N(C)CC34C5=c6ccc7c8ccc9c%10ccc%11c%12ccc%13c%14c(c%15c%16c3c6c7c3c8c9c6c%10c%11c(c%14%12)c%15c6c%163)C24C=%13C=C5)c(OCCCN(C)C)c1OCCCN(C)C]

A device comprising the inverted perovskite solar cell is also described.

A tandem solar cell includes a first sub-cell comprising a perovskite layer having a thickness of 50 to 200 nanometers; a second sub-cell comprising a photoactive layer and an interlayer disposed on the photoactive layer, wherein the interlayer comprises a first fulleropyrrolidine having structure (I)

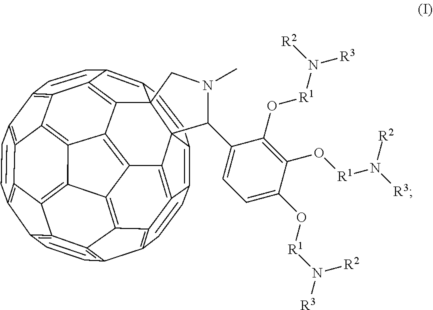

wherein R¹ is independently at each occurrence a divalent C₁₋₁₂ alkylene group, a C₆₋₃₀ arylene or heteroarylene group, or an alkylene oxide group; and R² and R³ are independently at each occurrence a hydrogen or a C₁₋₁₂ alkyl group; and an interconnecting layer disposed between the first sub-cell and the second sub-cell, wherein the interconnecting layer comprises a second fulleropyrrolidine having structure (V)

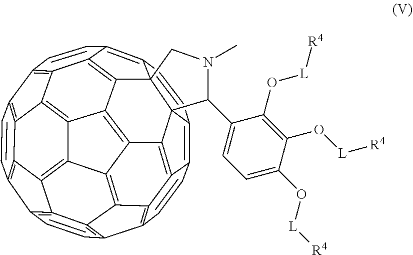

wherein L is independently at each occurrence a divalent C₁₋₁₆ alkylene group, C₆₋₃₀ arylene or heteroarylene group, or alkylene oxide group; and R⁴ is independently at each occurrence a zwitterion having the structure -A-B—X; wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero.

Another embodiment is a tandem solar cell comprising a first sub-cell comprising: an anode substrate; a perovskite layer having a thickness of 50 to 200 nanometers; a first hole transport layer disposed between the anode substrate and the perovskite layer; and a first electron transport layer comprising fullerene or a derivative thereof disposed on the perovskite layer; a second sub-cell comprising: a photoactive layer; a metal cathode layer; and an interlayer disposed between the photoactive layer and the metal cathode layer, wherein the interlayer comprises a first fulleropyrrolidine having structure (I), wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group; and an interconnecting layer disposed between the electron transport layer of the first sub-cell and the photoactive layer of the second sub-cell, wherein the interconnecting layer comprises: a second hole transport layer; a metal recombination layer disposed on the second hole transport layer; and a second electron transport layer disposed on the metal recombination layer on a side opposite the second hole transport layer, the second electron transport layer comprising a second fulleropyrrolidine having structure (V); wherein L is independently at each occurrence a divalent C₁₋₁₆ alkylene group, C₆₋₃₀ arylene or heteroarylene group, or alkylene oxide group; and R⁴ is independently at each occurrence a zwitterion having the structure -A-B—X; wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero; and wherein the first electron transport layer of the first sub-cell is in contact with at least a portion of the second electron transport layer of the interconnecting layer and the photoactive layer of second sub-cell is in contact with at least a portion of the second hole transport layer of the interconnecting layer.

A method of making a tandem solar cell includes forming a first hole transport layer on an anode substrate; forming a perovskite layer on the first hole transport layer, wherein forming the perovskite layer comprises: coating a perovskite precursor solution on the first hole transport layer at a temperature of 70 to 120° C. to form a perovskite precursor film disposed on the first hole transport layer; and annealing the perovskite precursor film to provide the perovskite layer; forming a first electron transport layer on the perovskite layer; forming a second electron transport layer on the first electron transport layer, the second electron transport layer comprising a second fulleropyrrolidine having structure (V) wherein L is independently at each occurrence a divalent C₁₋₁₆ alkylene group, C₆₋₃₀ arylene or heteroarylene group, or alkylene oxide group; and R⁴ is independently at each occurrence a zwitterion having the structure -A-B—X; wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero; forming a metal recombination layer on the second electron transport layer; forming a second hole transport layer on the metal recombination layer; forming a photoactive layer on the second hole transport layer; forming an interlayer on the photoactive layer, wherein the interlayer comprises a first fulleropyrrolidine having structure (I), wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group; and forming a metal cathode layer on the interlayer to provide the tandem solar cell.

A device comprising the above-described tandem solar cell is also disclosed, wherein the tandem solar cell is a power source for the device.

These and other embodiments are described in detail below.

### BRIEF DESCRIPTION OF THE DRAWINGS

The following figures are of exemplary embodiments, wherein like elements are numbered alike:

FIG. 1 is a representative perovskite solar cell, where the solar cell includes a metal cathode layer (1), an interlayer (2), an electron transport layer (3), a photoactive layer (4), a hole transport layer (5), and an anode layer (6).

FIG. 2 shows (a) an exemplary device architecture and molecular structure of a fulleropyrrolidine as an interlayer material; (b) energy level diagram of the device (interfacial dipole value is obtained by ultraviolet photoelectron spectroscopy (UPS) measurement); and (c) a cross-sectional scanning electron microscope (SEM) image of the device.

FIG. 3 shows the x-ray diffraction (XRD) of mixed counterion perovskite crystals formed by combining MAI and FAI with PbI₂.

FIG. 4 shows (a) a J-V curve of the devices with and without a fulleropyrrolidine interlayer; (b) power conversion efficiency (PCE) histogram of 85 devices containing fulleropyrrolidine interlayers; (c) hysteresis investigation of the device with fulleropyrrolidine interlayer; and d) the corresponding external quantum efficiency (EQE) profile.

FIG. 5 shows the V_{OC}, J_{SC}, FF and PCE histogram of 85 devices containing a fulleropyrrolidine interlayer.

FIG. 6 shows (a) a Nyquist plot of planar heterojunction perovskite solar cells. Dashed lines represent the recombination semicircle. Characteristic frequencies are highlighted with solid symbols; and (b) Mott-Schottky plot of two perovskite samples measured at 10 kHz probe frequency.

FIG. 7 shows surface potential maps from Kelvin probe force micros copy (KPFM) measurements for (a) bare Ag, (b) PCBM/Ag, and (c) Ag/C₆₀—N. (d) Representative V_{CPD} histograms of surface potential maps offset to put V_{CPD} of Ag at 0 V to better show ΔV_{CPD} with PCBM and C₆₀—N. (e) V_{CPD} histograms of surface potential maps of Ag electrodes peeled from as-prepared devices with and without C₆₀—N interlayer at three different locations each.

FIG. 8 shows topographic atomic force microscopy (AFM) and KPFM surface potential maps for (a,b) Ag, (c,d) Ag/PCBM, and (e,f) Ag/C₆₀—N respectively.

FIG. 9 shows (a,b) optical micrographs with AFM probe for scale of the underside of Ag electrodes peeled off of devices without and with C₆₀—N interlayers respectively. Topographic AFM and KPFM surface potential maps for (c,d) Ag electrodes from devices without C₆₀—N interlayers and (e,f) with C₆₀—N interlayers respectively.

FIG. 10 shows contact angle measurement of (a) perovskite film; (b) C₆₀—N thin film and (c) PC₆₁BM thin film (the water droplet is 100 microliters).

FIG. 11 shows the proton nuclear magnetic resonance (¹H NMR) spectrum of MAI.

FIG. 12 shows the proton nuclear magnetic resonance (¹H NMR) spectrum of FAI.

FIG. 13 is a schematic representation of a tandem perovskite/polymer solar cell.

FIG. 14 shows (a) transmittance measurement of the perovskite films with different thickness (inset: the film thickness increases from left to right); (b) powder x-ray diffraction (PXRD) for precursors and perovskite; representative scanning electron microscope (SEM) image (c) of a perovskite film with a thickness of 90 nm and its corresponding atomic force microscopy (AFM) image (d).

FIG. 15 shows SEM images of perovskite films on ITO/PEDOT:PSS substrates with different film thickness: (a) 70 nm; (b) 90 nm; (c) 110 nm; (d) 160 nm.

FIG. 16 shows AFM images of perovskite films on ITO/PEDOT:PSS substrates with different film thickness: (a) 70 nm; (b) 90 nm; (c) 110 nm: (d) 160 nm.

FIG. 17 shows (a) current density vs. bias voltage (J-V) curves of perovskite single junction solar cells (ITO/PEDOT:PSS/Perovskite/PC₆₁BM/C₆₀—N/Ag) with different perovskite layer thickness; (b) J-V curve of polymer single junction solar cell (ITO/PEDOT:PSS/Polymer BHJ/C₆₀—N/Ag) with a bulk heterojunction (BHJ) layer thickness of 100 nm; (c) ultraviolet-visible (UV/Vis) absorption of perovskite and polymer bulk heterojunction (BHJ) films; (d) external quantum efficiency (EQE) profiles of exemplary perovskite and polymer single junction solar cells.

FIG. 18 shows (a) device structure of tandem perovskite/polymer solar cells and the molecular structures of the interlayer materials: (b) cross-sectional SEM image of a tandem device with a perovskite layer thickness of 90 nm; (c) energy level diagram of the device (interfacial dipole values obtained by ultraviolet photoelectron spectroscopy (UPS))

FIG. 19 shows the chemical structures of PCE-10 and PC₇₁BM.

FIG. 20 shows cross-sectional SEM images of the tandem devices with different perovskite layer thickness: (a) 70 nm; (b) 90 nm; (c) 110 nm; (d) 160 nm (scale bar is 500 nm).

FIG. 21 shows device performance of perovskite/polymer tandem solar cells. (a) J-V curves of polymer/perovskite hybrid tandem solar cells with different perovskite layer thickness. (b) EQE profiles of polymer/perovskite hybrid tandem solar cells with different perovskite layer thickness. (c) J-V curve of polymer/perovskite hybrid tandem solar cells with the best FF value. (d) J-V curve of polymer/perovskite hybrid tandem solar cells with the best V_{OC} value.

FIG. 22 shows (a) J-V curves and device metrics of the optimal polymer/perovskite hybrid tandem solar cell (ITO/PEDOT:PSS/Perovskite/PC₆₁BM/C₆₀—SB/Ag/MoO₃/Polymer BHJ/C₆₀—N/Ag) under both forward and reverse scans and corresponding EQE profile (b).

FIG. 23 shows histograms of power conversion efficiency (PCE), fill factor (FF), short circuit current density (J_{SC}) and open circuit voltage (V_{OC}) based on 63 independent tandem devices.

### DETAILED DESCRIPTION

Interface engineering is critical for achieving efficient solar cells, yet a comprehensive understanding of the chemistry at the interface between metal electrode and electron transport layer (ETL) is lacking. The present inventors have determined that a significant power conversion efficiency (PCE) improvement of fullerene/perovskite planar heterojunction solar cells (e.g., 7.50% to 15.48%) can be achieved by inserting a fulleropyrrolidine interlayer between a metal electrode and the electron transport layer (ETL). The interface between metal electrode and ETL was carefully examined using a variety of electrical and surface potential techniques. Electrochemical impedance spectroscopy (EIS) measurements demonstrate that the interlayer enhances recombination resistance, increases electron extraction rate and prolongs free carrier lifetime. Kelvin probe force microscopy (KPFM) was used to map the surface potential of the metal electrode and it indicates a uniform and continuous work function decrease in the presence of the fulleropyrrolidine interlayer. Additionally, the planar heterojunction fullerene/perovskite solar cells are shown to have good stability under ambient conditions.

Furthermore, the present inventors have also determined that tandem photovoltaic devices having reduced thickness perovskite layers and good efficiencies can be obtained by combining thin perovskite layers with low band gap conjugated polymers to supplement the absorption and boost the efficiency. The present inventors demonstrate facile solution-based fabrication of high performance tandem perovskite/polymer solar cells where the front sub-cell includes a thin perovskite layer (e.g., less than 200 nanometers) and the back sub-cell includes a polymer-containing layer. Using the approach demonstrated herein, an unexpected maximum power conversion efficiency (PCE) of 16.0% was achieved with high open circuit voltage (V_{OC}), fill factor (FF) and low hysteresis, demonstrating the advantageous synergy between perovskite and semiconducting polymers in tandem solar cells.

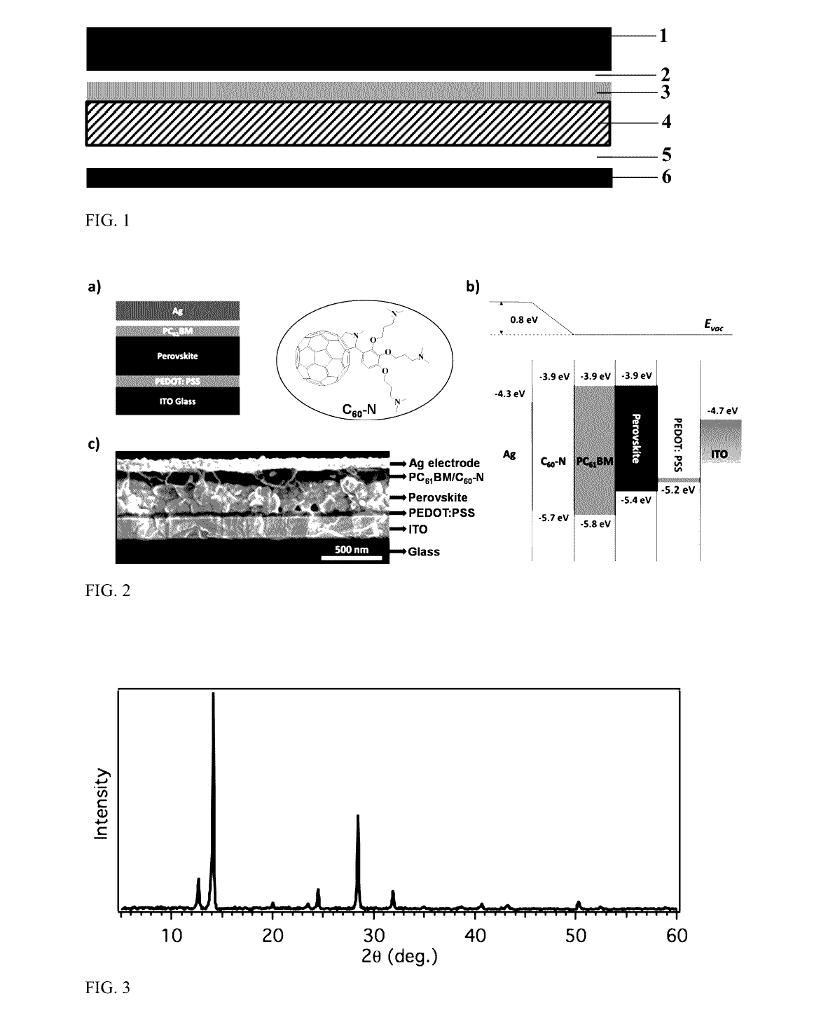

Accordingly, one aspect of the present disclosure is an inverted perovskite solar cell. In some embodiments, the solar cell is preferably a planar heterojunction solar cell. The inverted perovskite solar cell comprises an anode substrate, a photoactive layer comprising a perovskite, a hole transport layer disposed between the anode substrate and the photoactive layer, an electron transport layer comprising fullerene or a derivative thereof disposed on the photoactive layer, a metal cathode layer, and an interlayer disposed between the electron transport layer and the metal cathode layer. The inverted perovskite solar cell can have a structure as depicted in FIG. 1. FIG. 1 shows a cross-sectional view of solar cell comprising an anode substrate (6) and a hole transport layer (5) disposed on the anode substrate (6). The photoactive layer (4) is disposed on the hole transport layer (5) on a side opposite the anode substrate. The electron transport layer (3) is disposed on the photoactive layer (4) on a side opposite the hole transport layer (5). The interlayer (2) is disposed on the electron transport layer (3) on a side opposite the photoactive layer (4). The metal cathode layer (1) is disposed on the interlayer (2) on a side opposite the electron transport layer (3).

The interlayer comprises a fulleropyrrolidine having a structure (I)

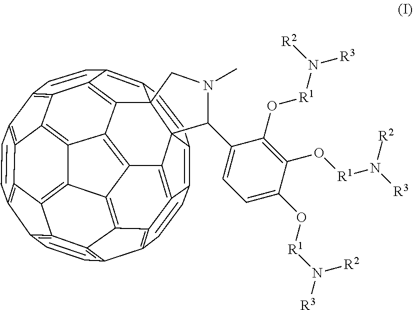

wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group. As used herein, a divalent alkylene oxide group is a group having the formula —(R^{a}—O)ₙ—R^{b}—, wherein R^{a} and R^{b} are independently at each occurrence a C₁₋₆ alkylene group, and n is an integer from 1 to 50, for example 1 to 10, for example 1 to 4 (e.g., ethylene oxide, propylene oxide, butylene oxide, poly(ethylene oxide), and the like). In some embodiments, R¹ at each occurrence is a divalent alkylene group. In some embodiments, R¹ is a divalent C₁₋₁₂ alkylene group, and each occurrence of R² and R³ are hydrogen. In some embodiments, R¹ is a divalent C₁₋₁₂ alkylene group, R² is a C₁₋₁₂ alkyl group, and R³ is hydrogen. In some embodiments, R¹ is a divalent C₁₋₁₂ alkylene group, and each occurrence of R² and R³ is a C₁₋₁₂ alkyl group. In some embodiments, R¹ is a divalent C₁₋₆ alkylene group, for example, a divalent propylene group. In some embodiments, each occurrence of R² and R³ is a C₁₋₆ alkyl group, preferably a methyl group. In an embodiment, the interlayer comprises the fulleropyrrolidine of structure (I), wherein R¹ is a divalent propylene group, and each occurrence of R² and R³ is a methyl group.

In some embodiments, the interlayer comprising the fulleropyrrolidine can have a thickness of 1 to 100 nanometers, for example 1 to 50 nanometers, for example 1 to 25 nanometers, for example 5 to 25 nanometers, for example 5 to 15 nanometers, for example 5 to 10 nanometers.

The interlayer comprising the fulleropyrrolidine is disposed between a metal cathode layer and an electron transport layer. The metal cathode layer can include, for example, calcium (Ca), aluminum (Al), Magnesium (Mg), titanium (Ti), tungsten (W), silver (Ag), gold (Au), platinum (Pt), indium (In), tin (Sn), gallium (Ga) and the like, or alloys or oxides of these metals. In some embodiments, the metal cathode comprises silver. In some embodiments, the metal cathode layer can have a thickness of 10 to 250 nm.

The electron transport layer can include, for example, a fullerene or a derivative thereof. Suitable fullerenes include C₆₀, C₇₀, C₇₆, C₇₈, C₈₂, C₈₄, C₉₂, and the like, and suitable fullerene derivatives include (6,6)-phenyl-C₇₁ butyric acid methyl ester (PC₇₁BM) and (6,6)-phenyl-C₆₁ butyric acid methyl ester (PC₆₁BM). Combinations of any of the foregoing fullerenes or fullerene derivatives can also be used. In some embodiments, the electron transport layer comprises C₆₀, (6,6)-phenyl-C₇₁ butyric acid methyl ester, (6,6)-phenyl-C₆₁ butyric acid methyl ester, or a combination thereof. In an embodiment, the electron transport layer comprises (6,6)-phenyl-C₆₁ butyric acid methyl ester.

In addition to the interlayer, the metal cathode layer, and the electron transport layer, the solar cell also includes a photoactive layer. As described above, the photoactive layer is disposed on the electron transport layer on a side opposite the interlayer. The photoactive layer comprises a perovskite material. As used herein, the term “perovskite” refers to the “perovskite structure” and not specifically to the perovskite material calcium titanate oxide (CaTiO₃). As used herein, “perovskite” or “perovskite material” refers to any material that have the same type of crystal structure as calcium titanate oxide and of materials in which the bivalent cation is replaced by two separate monovalent cations. The perovskite structure has the general stoichiometry AXY₃, where “A” and “X” are cations and “Y” is an anion. The “A” and “X” cations can have a variety of charges and in the original perovskite mineral (CaTiO3), the A cation is divalent and the X cation is tetravalent. For the purposes of this disclosure, the perovskite formulae includes structures having three (3) or four (4) anions, which can be the same or different, or one or two organic cations, or metal atoms carrying two or three positive charges, in accordance with the formulae presented herein. Organic-inorganic perovskites are hybrid materials exhibiting combined properties of organic composites and inorganic crystalline materials. The inorganic component forms a framework bound by covalent and ionic interactions which provide high carrier mobility. The organic component helps in the self-assembly process of those materials, and it also enables the hybrid materials to be deposited by low-cost techniques, similar to other organic materials. An additional important property of the organic component is to tailor the electronic properties of the organic-inorganic material by reducing its dimensionality and the electronic coupling between the inorganic sheets.

In some embodiments, the perovskite is a perovskite material having a structure (II)

CₙH₂ₙ₊₁NH₃XY₃ (II)

wherein n is independently at each occurrence an integer from 1 to 9 (e.g., 1, 2, 3, 4, 5, 6, 7, 8, or 9); X is independently at each occurrence lead, tin, or germanium; and Y is independently at each occurrence iodide, bromide, or chloride. In some embodiments, n is 1. In some embodiments, X is lead. In some embodiments, Y is iodide. In an embodiments, n is 1, X is lead, and Y is iodide. In some embodiments, the perovskite is a perovskite material having a structure (III)

H₂NCHNH₂XY₃ (III)

wherein X is independently at each occurrence lead, tin, or germanium; and Y is independently at each occurrence iodide, bromide, or chloride. In some embodiments, X is lead. In some embodiments, Y is iodide. In an embodiments, n is 1, X is lead, and Y is iodide. In some embodiments, the photoactive layer comprises a combination of two or more perovskites. In some embodiments, the perovskite materials according to structures (II) and (III) are present in the photoactive layer in a weight ratio of 0.1:1 to 1:0.1. In an embodiment, the perovskite materials according to structures (II) and (III) are present in the photoactive layer in a weight ratio of 1:1.

In some embodiments, the photoactive layer excludes a polymer, for example a conjugated polymer. In this context, the word “excludes” means that the photoactive layer includes less than or equal to 1 weight percent of a polymer, specifically less than or equal to 0.1 weight percent of a polymer, more specifically no polymer is included.

The photoactive layer can have a thickness of 100 to 500 nanometers, for example 200 to 400 nanometers. In an embodiment, the photoactive layer can have a thickness of 300 nanometers.

In addition to the interlayer, the metal cathode layer, the electron transport layer, and the photoactive layer, the solar cell also comprises a hole transport layer. As described above, the hole transport layer is disposed between the anode substrate and the photoactive layer.

The hole transport layer can comprise, for example, poly(ethylenedioxythiophene) and polystyrene sulfonate (PEDOT:PSS). In some embodiments, the hole transport layer can have a thickness of 30 to 200 nm.

The anode substrate can comprise indium tin oxide. In some embodiments, the anode substrate is an indium tin oxide glass substrate. In some embodiments, the anode substrate is at least partially transparent to light such that the solar cell can receive light from any suitable source of solar energy, for example, the sun.

In an embodiment, an inverted perovskite solar cell comprises an anode substrate comprising indium tin oxide; a photoactive layer comprising a perovskite; a hole transport layer disposed between the anode substrate and the photoactive layer; an electron transport layer comprising fullerene or a derivative thereof disposed on the photoactive layer; a metal cathode layer comprising silver; and an interlayer disposed between the electron transport layer and the metal cathode layer, wherein the interlayer comprises a fulleropyrrolidine having a structure (IV)

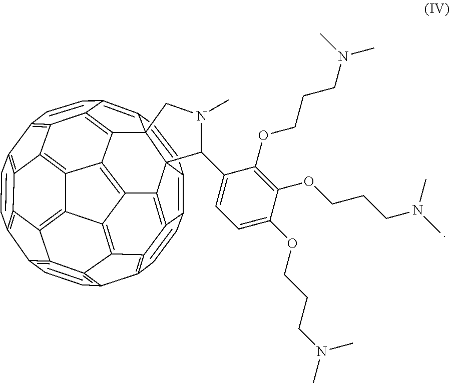 [SMILES: CN(C)CCCOc1ccc(C2N(C)CC34C5=c6ccc7c8ccc9c%10ccc%11c%12ccc%13c%14c(c%15c%16c3c6c7c3c8c9c6c%10c%11c(c%14%12)c%15c6c%163)C24C=%13C=C5)c(OCCCN(C)C)c1OCCCN(C)C]

In some embodiments, the inverted perovskite solar cells can exclude any polymer other than a suitable hole transport layer polymer (e.g., poly(ethylenedioxythiophene) and polystyrene sulfonate (PEDOT:PSS)).

The inverted perovskite solar cells can exhibit a power conversion efficiency (PCE) of at least 10%, for example at least 11.5%, for example at least 12%, for example at least 13%, for example at least 15%. In some embodiments, the perovskite solar cell exhibits a power conversion efficiency that is at least 50% greater than a perovskite solar cell not including the interlayer comprising a fulleropyrrolidine. Unexpectedly, the perovskite solar cells described herein can also exhibit improved stability in air (i.e., the perovskite solar cells including a fulleropyrrolidine interlayer are less prone to degradation compared to a perovskite solar cell not include the fulleropyrrolidine interlayer. In some embodiments, the perovskite solar cell retains a significant portion of its initial power conversion efficiency following storage in air. For example, the perovskite solar cell can have a power conversion efficiency after storing in air for up to two months that is 0 to 50% less than the initial power conversion efficiency of the perovskite solar cell. Stated another way, after storage in air for up to two months, the perovskite solar cell exhibits a power conversion efficiency that has not decreased by more than 50% compared to the initial power conversion efficiency.

The inverted perovskite solar cells described herein can be prepared using various techniques that are generally known for preparing perovskite-containing planar heterojunction solar cells, for example using sequential deposition. For example a solution comprising a hole transport layer material can be coated (e.g., by spin coating) on an anode substrate. To prepare the photoactive layer, a solution containing the desired metal cation (e.g., lead (II) iodide) can be prepared and coated (e.g., by spin coating) on the hole transport layer. A solution comprising the organic components (e.g., methyl ammonium iodide (MAI) and formamadinium iodide (FAI)) can be coated (e.g., by drop casting) on the metal cation layer. The desired perovskite structures are subsequently formed by annealing. The electron transport layer can be coated (e.g., by spin coating) on the photoactive layer. The interlayer can be coated (e.g., by spin coating) on the electron transport layer. Finally, the metal cathode layer can be deposited using thermal evaporation techniques. In some embodiments, the metal cathode layer can alternatively be solution cast, for example from a slurry comprising the metal. The solution casting of each successive layer is preferably carried out using a solvent such that the previous layer is not removed during deposition. An exemplary method of making the solar cells is further described in the working examples below.

The perovskite solar cells described herein can be incorporated in various articles, for example electronic devices. The perovskite solar cell can serve as a power source for the article or device.

Another aspect of the present disclosure is a tandem solar cell. The tandem solar cell comprises a first sub-cell, a second sub-cell, and an interconnecting layer disposed between the first sub-cell and the second sub-cell. In some embodiments, the first sub-cell can also be referred to as the front sub-cell, and the second sub-cell can also be referred to as the back sub-cell.

The first sub-cell comprises a perovskite layer having a thickness of 50 to 200 nanometers. In some embodiments, the perovskite layer can have a thickness of 50 to 200 nanometers, or 50 to less than 200 nanometers, or 50 to 180 nanometers, or 70 to 160 nanometers, or 70 to 150 nanometers, or 70 to 120 nanometers, or 70 to 110 nanometers. As used herein and as described above, the term “perovskite” refers to the “perovskite structure” and not specifically to the perovskite material calcium titanate oxide (CaTiO₃). Thus, “perovskite” or “perovskite material” refers to any material that have the same type of crystal structure as calcium titanate oxide and of materials in which the bivalent cation is replaced by two separate monovalent cations. The perovskite structure has the general stoichiometry AXY₃, where “A” and “X” are cations and “Y” is an anion. The “A” and “X” cations can have a variety of charges and in the original perovskite mineral (CaTiO3), the A cation is divalent and the X cation is tetravalent. For the purposes of this disclosure, the perovskite formulae includes structures having three (3) or four (4) anions, which can be the same or different, or one or two organic cations, or metal atoms carrying two or three positive charges, in accordance with the formulae presented herein. Organic-inorganic perovskites are hybrid materials exhibiting combined properties of organic composites and inorganic crystalline materials. The inorganic component forms a framework bound by covalent and ionic interactions which provide high carrier mobility. The organic component helps in the self-assembly process of those materials, and also enables the hybrid materials to be deposited by low-cost techniques, similar to other organic materials. An additional important property of the organic component is to tailor the electronic properties of the organic-inorganic material by reducing its dimensionality and the electronic coupling between the inorganic sheets.

In some embodiments, the perovskite layer can comprise a perovskite material having the structure (II)

CH₂H₂ₙ₊₁NH₃XY₃ (II)

wherein n is independently at each occurrence an integer from 1 to 9 (e.g., 1, 2, 3, 4, 5, 6, 7, 8, or 9); X is independently at each occurrence lead, tin, or germanium; and Y is independently at each occurrence iodide, bromide, or chloride. In some embodiments, n is 1. In some embodiments, X is lead. In some embodiments, Y is iodide. In an embodiment, n is 1, X is lead, and Y is iodide.

In addition to the perovskite layer, the first sub-cell can further include an anode substrate, a first hole transport layer disposed between the anode substrate and the perovskite layer, and a first electron transport layer disposed on the perovskite layer. The anode substrate can comprise indium tin oxide. In some embodiments, the anode substrate is an indium tin oxide glass substrate. In some embodiments, the anode substrate is at least partially transparent to light such that the solar cell can receive light from any suitable source of solar energy, for example, the sun.

The first hole transport layer can comprise, for example, poly(ethylenedioxythiophene) and polystyrene sulfonate (PEDOT:PSS). In some embodiments, the hole transport layer can have a thickness of 30 to 80 nm.

The first electron transport layer can include, for example, a fullerene or a derivative thereof. Suitable fullerenes include C₆₀, C₇₀, C₇₆, C₇₈, C₈₂, C₈₄, C₉₂, and the like, and suitable fullerene derivatives include (6,6)-phenyl-C₇₁ butyric acid methyl ester (PC₇₁BM) and (6,6)-phenyl-C₆₁ butyric acid methyl ester (PC₆₁BM). Combinations of any of the foregoing fullerenes or fullerene derivatives can also be used. In some embodiments, the first electron transport layer comprises C₆₀, (6,6)-phenyl-C1 butyric acid methyl ester, (6,6)-phenyl-C₆₁ butyric acid methyl ester, or a combination thereof. In an embodiment, the first electron transport layer comprises (6,6)-phenyl-C₆₁ butyric acid methyl ester.

The second sub-cell comprises a photoactive layer and an interlayer disposed on the photoactive layer. The interlayer comprises a first fulleropyrrolidine having structure (I) as described above. Specifically, the first fulleropyrrolidine of the interlayer of the second sub-cell can have the following structure (I)

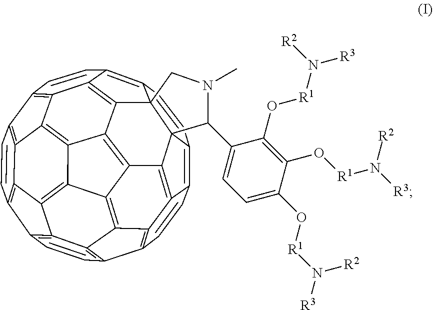

wherein R¹ is independently at each occurrence a divalent C₁₋₁₂ alkylene group, a C₆₋₃₀ arylene or heteroarylene group, or an alkylene oxide group; and R² and R³ are independently at each occurrence a hydrogen or a C₁₋₁₂ alkyl group. As used herein, a divalent alkylene oxide group is a group having the formula —(R^{a}—O)ₙ—R^{b}—, wherein R^{a} and R^{b} are independently at each occurrence a C₁₋₆ alkylene group, and n is an integer from 1 to 50, for example 1 to 10, for example 1 to 4 (e.g., ethylene oxide, propylene oxide, butylene oxide, poly(ethylene oxide), and the like). In some embodiments, R¹ at each occurrence is a divalent alkylene group. In some embodiments, R¹ is a divalent C₁₋₁₂ alkylene group, and each occurrence of R² and R³ are hydrogen. In some embodiments, R¹ is a divalent C₁₋₁₂ alkylene group, R² is a C₁₋₁₂ alkyl group, and R³ is hydrogen. In some embodiments, R¹ is a divalent C₁₋₁₂ alkylene group, and each occurrence of R² and R³ is a C₁₋₁₂ alkyl group. In some embodiments, R¹ is a divalent C₁₋₆ alkylene group, for example, a divalent propylene group. In some embodiments, each occurrence of R² and R³ is a C₁₋₆ alkyl group, preferably a methyl group. In an embodiment, the interlayer comprises the fulleropyrrolidine of structure (I), wherein R¹ is a divalent propylene group (e.g., a divalent 1,3-propylene group), and each occurrence of R² and R³ is a methyl group.

In some embodiments, the interlayer comprising the first fulleropyrrolidine can have a thickness of 1 to 100 nanometers, for example 1 to 50 nanometers, for example 1 to 25 nanometers, for example 5 to 25 nanometers, for example 5 to 15 nanometers, for example 10 to 15 nanometers.

The photoactive layer comprises a combination of at least one electron-donating material, for example a conjugated polymer or any other suitable electron-donating organic molecule, and at least one electron-accepting material, for example a fullerene (or fullerene derivative) or any other suitable electron-accepting organic molecule.

The electron-donating material can comprise poly(3-hexylthiophene) (P3HT), poly(p-phenylenevinylene) (PPV), poly[2-methoxy-5-(3,7-dimethyloctyloxy)-1,4-phenylene vinylene] (MDMO-PPV), poly(2-methoxy-5-(2′-ethyl-hexyloxy)-1,4-phenylene vinylene) (MEH-PPV), poly(2, 7-(9-(2′-ethylhexyl)-9-hexyl-fluorene)-alt-5,5-(4′,7′-di-2-thienyl-2′,1′,3′-benzothiadiazole)) (PFDTBT), poly(2,6-(4,4-bis-(2-ethylhexyl)-4H-cyclopenta(2,1-b;3,4-b′)dithiophene)-alt-4,7-(2,1,3-benzothiadiazole)) (PCPDTBT), poly(p-phenylene-ethynylene)-alt-poly(p-phenylene-vinylene) (PPE-PPV), poly((2,7-(9-(2′-ethylhexyl)-9-hexyl-fluorene)-alt-5,5-(4′,7′-di-2-thienyl-2′,1′,3′-benzothiadiazole))-co-(2,7-(9-(2′-ethylhexyl)-9-hexyl-fluorene)-alt-2,5-thiophene)) (APFO-5), poly(4,8-bis-alkyloxybenzo(1,2-b:4,5-b′)dithiophene-2,6-diyl-alt-(alkylthieno(3,4-b)thiophene-2-(2-ethyl-1-hexanone)-2,6-diyl)) (PBDTTT-C), poly(4,8-bis-alkyloxybenzo(1,2-b:4,5-b′)dithiophene-2,6-diyl-alt-(thieno(3,4-b)thiophene-2-carboxylate)-2,6-diyl) (PBDTTT-E); poly(N-9′-heptadecanyl-2,7-carbazole-alt-5,5-(4′,7′-di-2-thienyl-2′,1′,3′-benzothiadiazole)) (PCDTBT), poly[4,8-bis[(2-ethylhexyl) oxy]benzo[1,2-b:4,5-b′]dithiophene-2,6-diyl][3-fluoro-2-[(2-ethylhexyl)carbonyl]′ thieno[3,4-b]thiophenediyl] (PTB7), poly [(4,4′-bis(2-ethylhexyl)dithienol [3,2-b:2′,3′-d]silole)-2,6-diyl-alt-(2,1,3-benzothiadiazole)-4,7-diyl](PSBTBT), poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)] (also known as PCE-10, PBDTTT-EFT, or PTB7-Th) or a combination thereof.

The electron-accepting material can be, for example, fullerene (e.g., C₆₀, C₇₀, C₇₆, C₇₈, C₈₂, C₈₄, C₉₂, and the like), a fullerene derivative (e.g., PCBM, and the like), or a combination comprising at least one of the foregoing. In some embodiments, the electron-accepting material comprises (6,6)-phenyl-C₇₁ butyric acid methyl ester (PC₇₁BM), (6,6)-phenyl-C₆₁ butyric acid methyl ester (PC₆₁BM), or a combination thereof.

In some embodiments, the photoactive layer includes the electron-donating material and the electron accepting material in a weight ratio of 0.8:1 to 1:4, for example 1:1 to 1:2.

In some embodiments, the photoactive layer comprises poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)] and (6,6)-phenyl-C₇₁ butyric acid methyl ester. In some embodiments, the photoactive layer can have a thickness of 50 to 500 nm, preferably about 100 nm, as measured using profilometry.

The tandem solar cells can further include a metal cathode layer, wherein the interlayer is disposed between the photoactive layer and the metal cathode layer. The metal cathode layer can include, for example, calcium (Ca), aluminum (Al), Magnesium (Mg), titanium (Ti), tungsten (W), silver (Ag), gold (Au), platinum (Pt), indium (In), tin (Sn), gallium (Ga) and the like, or alloys or oxides of these metals. In some embodiments, the metal cathode layer comprises silver. In some embodiments, the metal cathode layer can have a thickness of 10 to 250 nm.

The interconnecting layer comprises a second fulleropyrrolidine having structure (V)

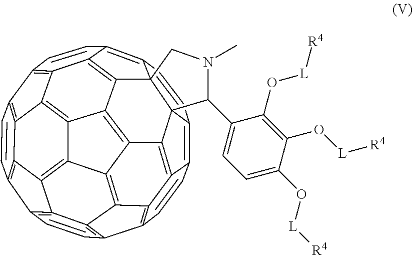

wherein L is independently at each occurrence a divalent C₁₋₁₆ alkylene group, C₆₋₃₀ arylene or heteroarylene group, or alkylene oxide group. In some embodiments, L is independently at each occurrence a divalent C₁₋₁₆ alkylene group, for example a propylene group, in particular a 1,3-propylene group (i.e., —(CH₂)₃—). R⁴ is independently at each occurrence a zwitterion having the structure -A-B—X, wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero (i.e., the zwitterion is net neutral). For example, in an embodiment wherein A is a center of permanent positive charge, X is a center of permanent negative charge. For example, in an embodiment wherein A is a center of permanent negative charge, X is a center of permanent positive charge. In some embodiments, a center of permanent positive charge can include a quaternary ammonium group, a phosphonium group, a sulfonium group, and the like. In some embodiments, the center of permanent positive charge is preferably an ammonium group. In some embodiments, a center of permanent negative charge can include a sulfonate group, a phosphonate group, a carboxylate group, a thiolate group, and the like.

In some embodiments, each occurrence of R⁴ can be a sulfobetaine zwitterion, a phosphorylcholine zwitterion, a carboxybetaine zwitterion, a phosphobetaine zwitterion, or a combination thereof. For example, in some embodiments, each occurrence of R⁴ is a sulfobetaine zwitterion having the structure (VI)

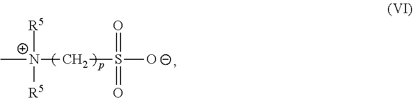

wherein R¹ is independently at each occurrence a substituted or unsubstituted C₁₋₁₂ alkyl group; and p is independently at each occurrence an integer from 1 to 12. In some embodiments, each occurrence of R⁵ is methyl. In some embodiments, p is an integer from 1 to 6, for example, in some embodiments p is equal to 3.

The fulleropyrrolidine according to structure (V) is preferably present as a second electron transport layer. Thus, the interconnecting layer preferably comprises a second electron transport layer, a metal recombination layer, and a second hole transport layer. The second electron transport layer is disposed on the metal recombination layer on a side opposite the second hole transport layer. In some embodiments, the interconnecting layer can have a total thickness (i.e., including the second electron transport layer, the metal recombination layer, and the second hole transport layer) of 30 to 100 nm, or 40 to 75 nm, or 45 to 60 nm. In some embodiments, the second electron transport layer can have a thickness of 10 to 60 nm, or 15 to 55 nm, or 20 to 40 nm.

The metal recombination layer can include any suitable metal, and it is not required to be the same as the metal cathode layer. For example, the metal recombination layer can be, for example, aluminum (Al), silver (Ag), gold (Au), or a combination thereof. In some embodiments, the metal recombination layer comprises aluminum or silver. In some embodiments, the metal recombination layer comprises silver. In some embodiments, the metal recombination layer can have a thickness of 2 to 15 nm.

The second hole transport layer can be any suitable hole transport material, and can include a material that is the same or different as the first hole transport layer. In some embodiments, the second hole transport layer comprises a metal oxide, for example molybdenum oxide, vanadium oxide, tungsten oxide, and the like, or a combination thereof. In some embodiments, the second hole transport layer can have a thickness of 5 to 15 nm.

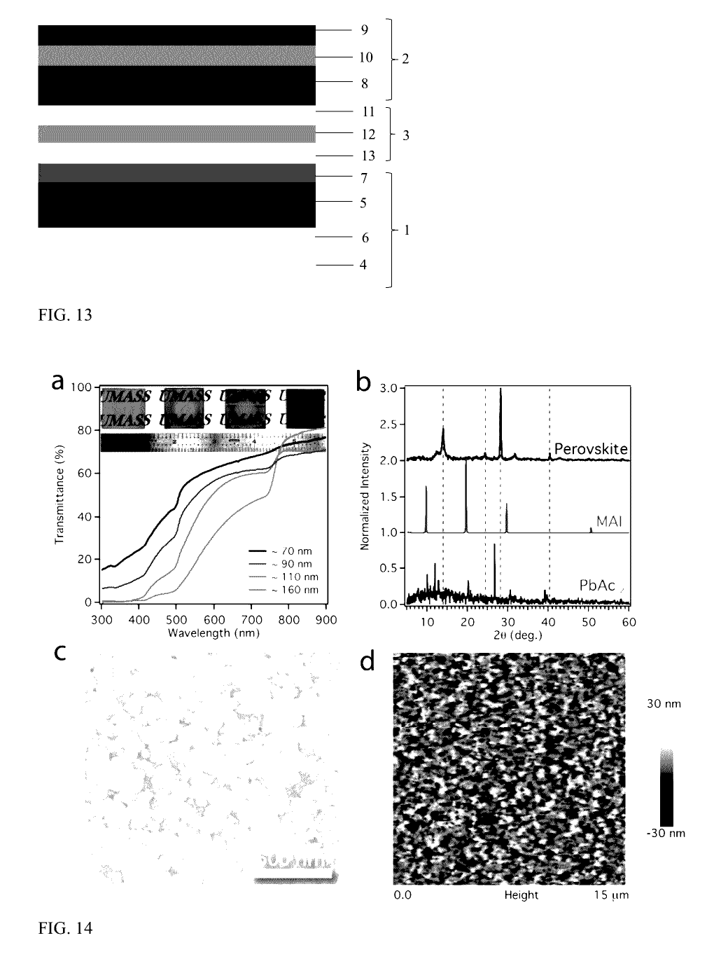

In an embodiment, the tandem solar cell can be as shown in FIG. 13. In particular, a tandem solar cell can comprise a first sub-cell (1) comprising an anode substrate (4), a perovskite layer (5) having a thickness of 50 to 200 nanometers, a first hole transport layer (6) disposed between the anode substrate (4) and the perovskite layer (5), and a first electron transport layer (7) disposed on the perovskite layer. The first electron transport layer preferably comprises fullerene or a derivative thereof. The tandem solar cell further comprises a second sub-cell (2) comprising a photoactive layer (8), a metal cathode layer (9), and an interlayer (10) disposed between the photoactive layer (8) and the metal cathode layer (9), wherein the interlayer comprises a first fulleropyrrolidine having structure (I), as described above. In an embodiment, the first fulleropyrrolidine can have structure (IV)

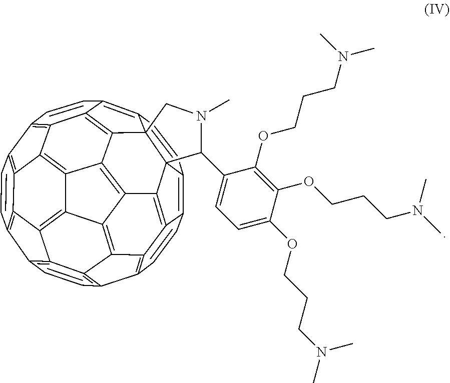 [SMILES: CN(C)CCCOc1ccc(C2N(C)CC34C5=c6ccc7c8ccc9c%10ccc%11c%12ccc%13c%14c(c%15c%16c3c6c7c3c8c9c6c%10c%11c(c%14%12)c%15c6c%163)C24C=%13C=C5)c(OCCCN(C)C)c1OCCCN(C)C]

The tandem solar cell further comprises interconnecting layer (3) disposed between the first electron transport layer (7) and the photoactive layer (8). The interconnecting layer (3) comprises a second hole transport layer (11), a metal recombination layer (12) disposed on the second hole transport layer (11), and a second electron transport layer (13) disposed on the metal recombination layer (12) on a side opposite the second hole transport layer (11). The second electron transport layer comprises a second fulleropyrrolidine having structure (V), as described above. In an embodiment, the second fulleropyrrolidine can have structure (VII)

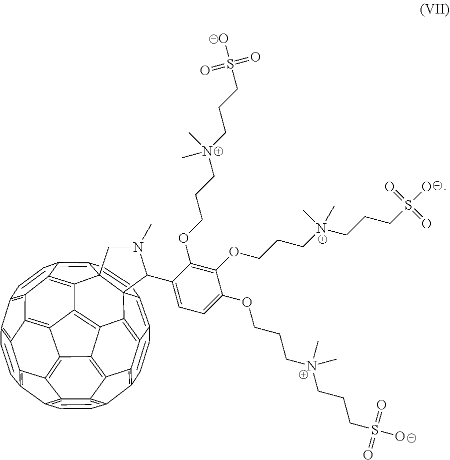 [SMILES: CN1CC23C4=c5ccc6c7ccc8c9ccc%10c%11ccc%12c%13c(c%14c%15c2c5c6c2c7c8c5c9c%10c(c%13%11)c%14c5c%152)C3(C=%12C=C4)C1c1ccc(OCCC[N+](C)(C)CCCS(=O)(=O)[O-])c(OCCC[N+](C)(C)CCCS(=O)(=O)[O-])c1OCCC[N+](C)(C)CCCS(=O)(=O)[O-]]

The first electron transport layer (7) of the first sub-cell (1) is in contact with at least a portion of the second electron transport layer (13) of the interconnecting layer. The photoactive layer (8) of the second sub-cell (2) is in contact with at least a portion of the second hole transport layer (11) of the interconnecting layer.

Another aspect of the present disclosure is a method of making the above-described tandem solar cells. In an embodiment, a method of making a tandem solar cell comprises forming a first hole transport layer on an anode substrate and forming a perovskite layer on the first hole transport layer. Forming the perovskite layer includes coating a perovskite precursor solution on the first hole transport layer at a temperature of 70 to 120° C., preferably 100° C. to form a perovskite precursor film disposed on the first hole transport layer; and annealing the perovskite precursor film to provide the perovskite layer. The method of making the tandem solar cell further comprises forming a first electron transport layer on the perovskite layer, forming a second electron transport layer on the first electron transport layer, wherein the second electron transport layer comprises a second fulleropyrrolidine having structure (V), as described above. The method further comprises forming a metal recombination layer on the second electron transport layer, forming a second hole transport layer on the metal recombination layer, forming a photoactive layer on the second hole transport layer, forming an interlayer on the photoactive layer, wherein the interlayer comprises a first fulleropyrrolidine having structure (I), as described above. Finally, a metal cathode layer is formed on the interlayer to provide the tandem solar cell.

In some embodiments, the forming of the first hole transport layer, the perovskite layer, the first electron transport layer, the second electron transport layer, the photoactive layer, and the interlayer comprises solution coating the layers. Forming the layers by solution coating can include methods such as solvent casting, spin coating, drop casting, ink jetting, doctor blading, dip coating, and the like. The solution casting of each successive layer is preferably carried out using a solvent such that the previous layer is not removed during deposition. The unique orthogonal solubility of each successive layer allows for this advantageous solution-based sequential deposition process. Furthermore, including the perovskite layer in the first sub-cell precludes the need to expose the polymer-containing photoactive layer of the second sub-cell to any annealing step. Stated another way, the perovskite layer is advantageously formed prior to the photoactive layer. Forming the metal recombination layer, the second hole transport layer, and the metal cathode layer can by thermal evaporation. An exemplary method of making the tandem solar cells is further described in the working examples below.

The tandem perovskite/polymer solar cells described herein can exhibit a power conversion efficiency of at least 90%, or at least 10% or at least 12%, or at least 13%, or at least 15%. In some embodiments, the tandem solar cells can exhibit a power conversion efficiency of 9 to 16% o, or 10 to 16%, or 10 to 15%, or 12 to 15%. In some embodiments, the tandem perovskite/polymer solar cells described herein can exhibit a fill factor that is at least 60%, or at least 65%, or at least 68%, or at least 70%. In some embodiments, the tandem perovskite/polymer solar cells can exhibit a fill factor that is 60 to 80%, or 60 to 78%, or 62 to 78%, or 64 to 78%, or 66 to 78%. In some embodiments, the tandem perovskite/polymer solar cells described herein can exhibit an open circuit voltage (V_{OC}) that is greater than or equal to 1.0 volt (V), for example 1.0 to 2.0 volts, or 1.20 to 2.0 volts, or 1.40 to 1.80 volts, or 1.50 to 1.80 volts.

The tandem perovskite/polymer solar cells described herein can be incorporated in various articles or devices, for example electronic devices. The tandem perovskite/polymer solar cell can serve as a power source for the article or device.

The perovskite-containing solar cells and methods of making the same are further illustrated by the following non-limiting examples.

### EXAMPLES

### Inverted Perovskite Solar Cells

Fullerene/perovskite planar heterojunction solar cells shown in FIG. 2(a) were fabricated by a sequential deposition process starting from indium tin oxide (ITO) (hole extracting electrode). See, e.g., J. Burschka, N. Pellet, S.-J. Moon, R. Humphry-Baker, P. Gao, M. K. Nazeeruddin, M. Gratzel, Nature 2013, 499, 316. The conducing polymer poly(3,4-ethylenedioxythiophene):poly(styrenesulfonate) (PEDOT:PSS), which is widely applied in polymer solar cells as a hole transport layer (HTL), was coated onto ITO to provide a high work function (Φ) electrode (FIG. 2). The lead (II) iodide (PbI₂) solution was then spin coated onto PEDOT: PSS modified ITO substrates, followed by thermal annealing, which is critical to promote the crystallization of the as-spun PbI₂ film. A mixture of methyl ammonium iodide (MAI) and formamadinium iodide (FAI) (1:1 by weight) was drop coated from isopropanol onto the crystallized PbI₂ film, followed by spin coating to remove excess solution. Thermal annealing was used to promote the reaction of MAI and FAI with PbI₂ to form perovskite crystals (FIG. 2). Shown in FIG. 2(c), the uniform perovskite crystals (approximately 150 nanometers) form condensed packing with a film thickness of about 300 nm. PC₆₁BM (ETL) was then spin coated onto the perovskite active layer from chlorobenzene, followed by a fulleropyrrolidine referred to as “C₆₀—N” as the interface modification layer from 2,2,2-trifluoroethanol (TFE), and finally Ag electrode (100 nm) was deposited by thermal evaporation. The chemical structure of the C₆₀—N used in the interlayer of the present examples is shown in FIG. 2(a).

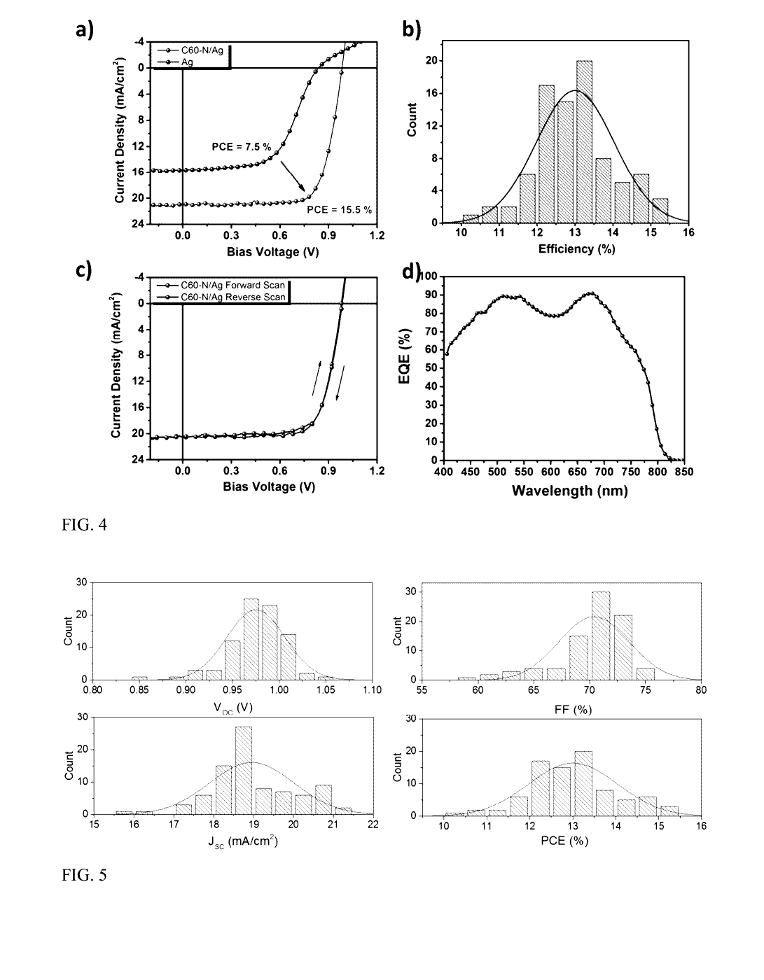

As shown in FIG. 4(a), the devices without C₆₀—N interlayers gave maximum power conversion efficiencies (PCEs) of 7.50%, noting the presence of an S-shaped J-V curve, which arises from carrier accumulation inside of the device. See, e.g., B. Qi, J. Wang, Phys. Chem. Chem. Phys. 2013, 15, 8972. The insertion of C₆₀—N interlayers led to good rectification with a maximum PCE of 15.48%, indicating enhanced carrier extraction from the active layer after surface modification with interlayer. PCE histogram shown in FIG. 4(b) indicates that the average efficiency is 13%, which is calculated from 85 devices. Device performance is summarized in Table 1 and FIG. 5.

TABLE 1

| | Device | | | | |
|---|---|---|---|---|---|
| Device Structure | Amount | V_{OC} (V) | J_{SC} (mA/cm²) | FF (%) | PCE (%) |
| Bare Ag cathode | 12 | 0.87 ± 0.01 | 15.93 ± 0.82 | 52.2 ± 4.1 | 7.17 ± 0.27 |
| Ag/C₆₀-N cathode | 85 | 0.98 ± 0.03 | 18.95 ± 1.06 | 70.4 ± 3.1 | 13.00 ± 1.04 |

Additionally, no J-V hysteresis was observed upon forward and reverse device sweeping, suggesting that the perovskite active layer and interfaces have a negligible number of defects, as shown in FIG. 4(c). See, e.g., H. J. Snaith, A. Abate, J. M. Ball, G. E. Eperon, T. Leijtens, N. K. Noel, S. D. Stranks, J. T.-W. Wang, K. Wojciechowski, W. Zhang, J. Phys. Chem. Lett. 2014, 5, 1511. The lack of hysteresis is important from a device characterization standpoint, since it removes variability arising from active layer imperfections, allowing emphasis to be given to the effects of interfacial engineering on device performance. External quantum efficiency (EQE) profile shown in FIG. 4(d) demonstrates a broad photo-response extending to about 800 nm with a peak EQE value of 91%.

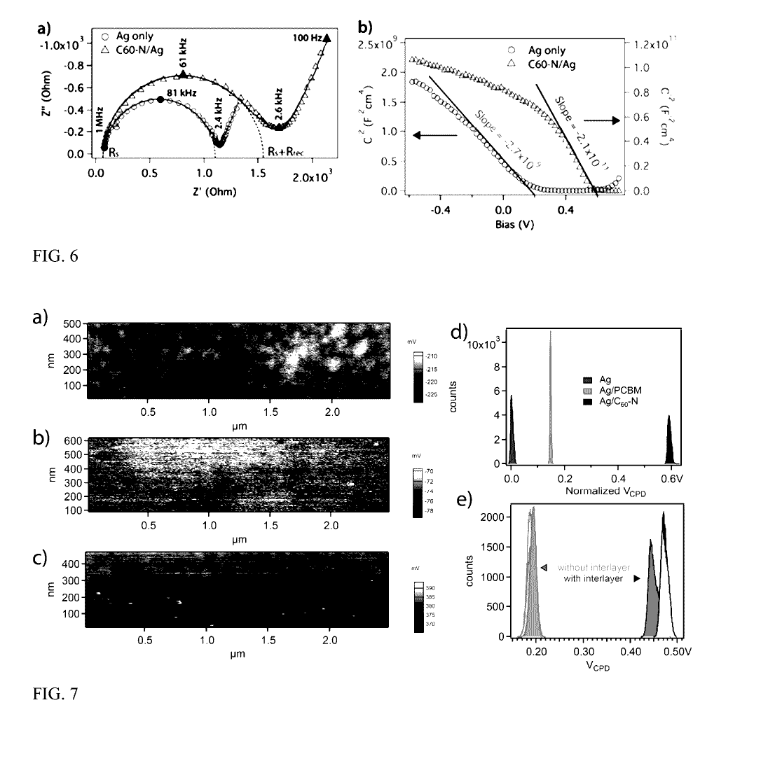

EIS characterization was also performed to understand the recombination losses and charge transport properties upon introducing a C₆₀—N interlayer between the ETL and Ag electrode. In the EIS measurement, a small AC voltage of 20 mV is applied under constant illumination to measure device impedance as a function of frequency (o), sweeping from 100 Hz to 1 MHz. The Nyquist plot shown in FIG. 6(a) has two distinct charge transport regimes; a low frequency component (<2.5 kHz) that arises predominantly from the slow relaxation/diffusion of ions, and a high frequency component (>2.5 kHz), originating from the electronic transport and recombination kinetics. At 0 V applied DC bias the high frequency impedance is associated with the recombination resistance (R_{rec}). We observed that the R_{rec} increased (shown as dotted lines in FIG. 6(a)) for devices containing a C₆₀—N interlayer compared to bare Ag devices, which leads to reduced recombination losses. See, e.g., E. J. Juarez-Perez, M. Wuβler, F. Fabregat-Santiago, K. Lakus-Wollny, E. Mankel, T. Mayer, W. Jaegermann, I. Mora-Sero, J. Phys. Chem. Lett. 2014, 5, 680. Additionally, the lifetime (τₙ) of free carriers increased from 12 μs to 16 μs for bare Ag to C₆₀—N/Ag devices, as calculated from the Nyquist plot. EIS measurements were also used to generate Mott-Schottky (MS) plots for bare Ag and C₆₀—N/Ag devices, where the interfacial charge density is inversely proportional to the slope of the MS plot, assuming an equivalent dielectric constant for both devices. The slope of the C₆₀—N/Ag devices is two orders of magnitude higher than bare Ag devices, indicating low interfacial charge density and thus excellent charge extraction at the metal electrode interface for the devices containing C₆₀—N. Additionally, the high charge accumulation at the PC₆₁BM/Ag interface for devices without an interlayer helps to explain the observed S-shaped J-V curve and low V_{OC} for the bare Ag device. These EIS measurements demonstrate the importance of an interlayer at the electron extracting electrode/ETL interface in planar heterojunction perovskite solar cells to reduce recombination losses and prevent interfacial charge build-up by assisting electron transport.

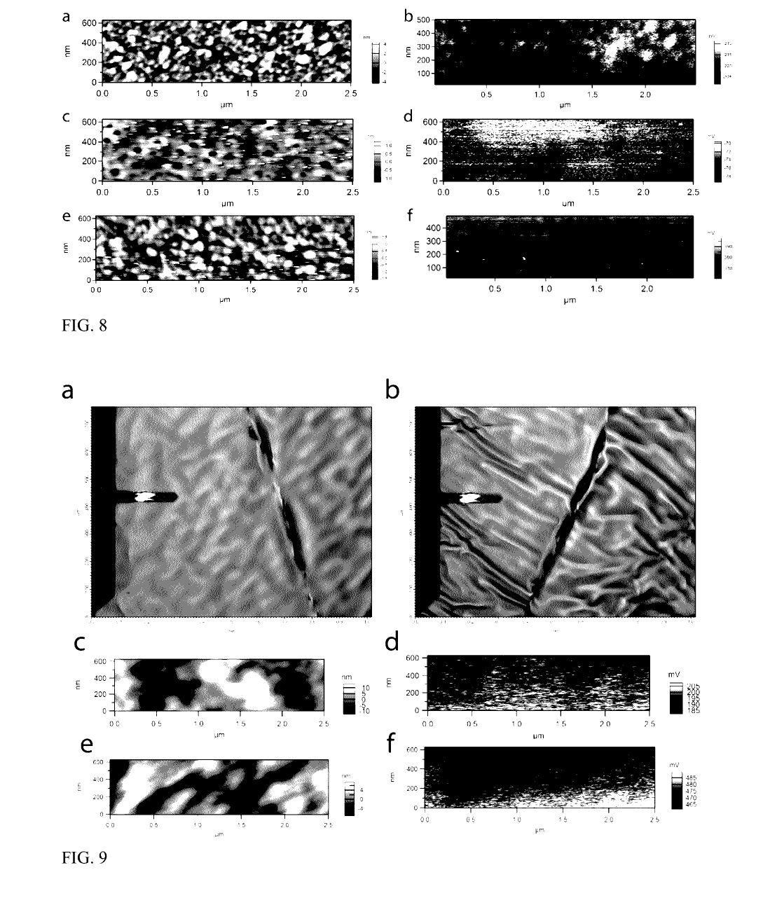

Kelvin probe force microscopy (KPFM) is an effective technique to understand the working mechanism of perovskite solar cells. See, e.g., P. Qin, A. L. Domanski, A. K. Chandiran, R. Berger, H.-J. Butt, M. I. Dar, T. Moehl, N. Tetreault, P. Gao, S. Ahmad, M. K. Nazeeruddin, M. Gratzel, Nanoscale 2014, 6, 1508; V. W. Bergmann, S. A. L. Weber, F. Javier Ramos, M. K. Nazeeruddin, M. Gratzel, D. Li, A. L. Domanski, I. Lieberwirth, S. Ahmad, R. Berger, Nat. Commun. 2014, 5, 5001. To further understand the interface modification in our devices, KPFM measurements were performed to determine the contact potential differences (V_{CPD}) between the atomic force microscopy (AFM) probe and bare Ag electrode, Ag/PC₆₁BM, or Ag/C₆₀—N. In a typical KPFM experiment, a first pass scan is done in mechanically driven tapping mode to measure topography, and then a second pass scan is done—so called nap mode—at Δz above the surface, where the cantilever is driven at its AC voltage resonant frequency to determine V_{CPD}. Potential differences between the Pt/Ir probe and the sample cause mechanical oscillations in the probe and are offset by an applied voltage (V_{DC}) via a potential feedback loop; therefore V_{DC}=V_{CPD}. See, e.g., V. Palermo, M. Palma, P. Samori, Adv. Mater. 2006, 18, 145. The samples for KPFM were prepared by evaporating Ag (70 nm) onto a clean Si wafer, followed by spin coating PC₆₁BM from chlorobenzene or C₆₀—N from TFE. Potential maps (FIGS. 7 and 8) were measured at three different locations on the sample, and the Si wafer was kept grounded throughout all measurements. Potential histograms were made and fit with Gaussian curves to find the mean V_{CPD} for the sample. Representative V_{CPD} histograms for Ag electrode, Ag/PC₆₁BM, and Ag/C₆₀—N are shown in FIG. 7(d), where the V_{CPD} of bare silver is offset to 0 V in order to represent the change in V_{CPD} for PC₆₁BM and C₆₀—N coated samples. By this method we found ΔV_{CPD} between bare Ag and Ag/PC₆₁BM to be 0.14±0.01 V, and between bare Ag and Ag/C₆₀—N to be 0.62±0.03 V By the equation (see, e.g., V. Palermo, M. Palma, P. Samori, Adv. Mater. 2006, 18, 145: V_{CPD}≈(Φ_{probe}−Φₛₐₘₚₗₑ)/−e we estimated a 0.62 eV Φ decrease when C₆₀—N is coated on Ag relative to bare Ag and 0.47 eV Φ decrease for C₆₀—N/Ag relative to PC₆₁BM/Ag. This apparent decrease in Ag Φ arises from the presence of a negative interfacial dipole between Ag and C₆₀—N, and explains the improved V_{OC} and rectification for devices containing C₆₀—N interlayers. Additionally ΔV_{CPD} of as-prepared devices was measured by peeling off the silver electrodes of the devices using Scotch® tape and making KPFM measurements on the underside of the electrodes for solar cells with and without C₆₀—N interlayers (FIG. 9). V_{CPD} histograms of potential maps at three different locations are shown in FIG. 7(e) for samples with and without C₆₀—N interlayer, showing a ΔV_{CPD}=0.27+0.01 V (decreasing Φ) for devices with C₆₀—N interlayers relative to those without (PC₆₁BM/Ag). Although a discrepancy exists between ΔV_{CPD} measured for freshly cast (0.47 V) vs. peeled (0.27 V) Ag substrates, the overall result (decreased Ag Φ) correlates well with the observed gain in V_{OC} for perovskite solar cells that have C₆₀—N interlayers.

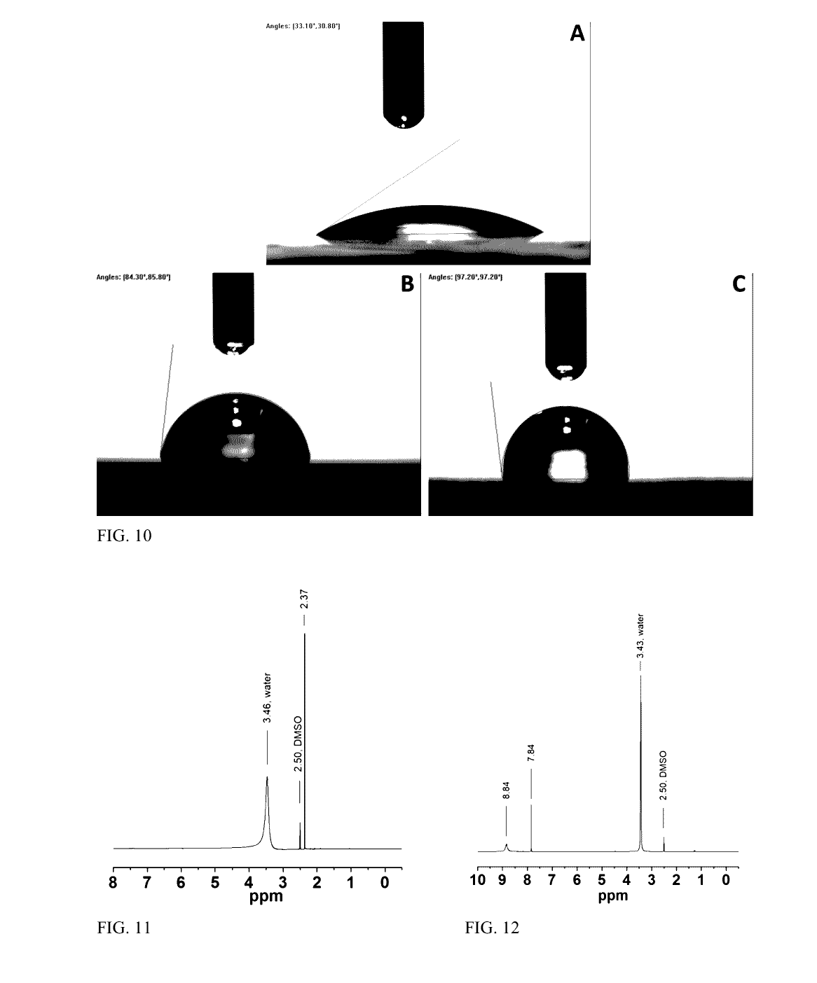

It has been shown that the half-life time of some perovskite solar cells with planar heterojunction architecture cannot surpass 2 days under ambient atmosphere. See, e.g., H. Zhou, Q. Chen, G. Li, S. Luo, T.-b. Song, H.-S. Duan, Z. Hong, J. You, Y. Liu, Y. Yang, Science 2014, 345, 542; D. Liu, J. Yang, T. L. Kelly, J. Am. Chem. Soc. 2014, 136, 17116. The ambient stability of the present devices was also characterized. The PCEs of these devices were observed to decrease in the initial 30 hours, with a 12% decrease on average. However, after storing for 30 hours in air, the PCEs of these devices remained relatively stable even up to 80 hours. After 2 months of storage in air it was found that these devices still maintained an average PCE of 6.50%. Though the reason for the stability of these devices is not clear, without wishing to be bound by theory, we speculate that the cover layer (C₆₀—N and PC₆₁BM) is more hydrophobic than a perovskite layer (demonstrated using contact angle measurements, as shown in FIG. 10) and works like an encapsulation layer that blocks the penetration of humidity. See, e.g., J. H. Heo, H. J. Han, D. Kim, T. K. Ahn, S. H. Im, Energy Environ. Sci. 2015, 8, 1602.

The present inventors have demonstrated a significant improvement in PCEs of fullerene/perovskite inverted planar heterojunction solar cells from 7.50%/o to 15.48% by inserting C₆₀—N as interlayer between metal electrode and ETL. A variety of electrical and surface potential characterization techniques were used to understand the interface between metal electrode and ETL. With the aid of these measurements, three basic questions about the role of interface engineering in inverted perovskite solar cells were answered: first, optimizing interface between metal electrode and ETL can enhance recombination resistance and reduce recombination loss; second, lowering work function of electron extracting electrode can increase electron extraction rate at perovskite/ETL interface; finally, a longer lifetime of the free carriers can be achieved by modification of this interface. KPFM characterization successfully mapped the surface potential of Ag electrode with and without surface modification, indicating a uniform and continuous work function decrease after surface modification. The mapping results of the Ag electrode surface directly contacted with ETL in real devices show an apparent work function decrease after the insertion of C₆₀—N interlayer, which correlates well with the V_{OC} gain seen in actual devices. Besides clarifying these important issues, the stability investigation of these devices indicates that interface engineering is a promising method for achieving high performance and air stable inverted perovskite solar cells.

### Tandem Perovskite Solar Cells

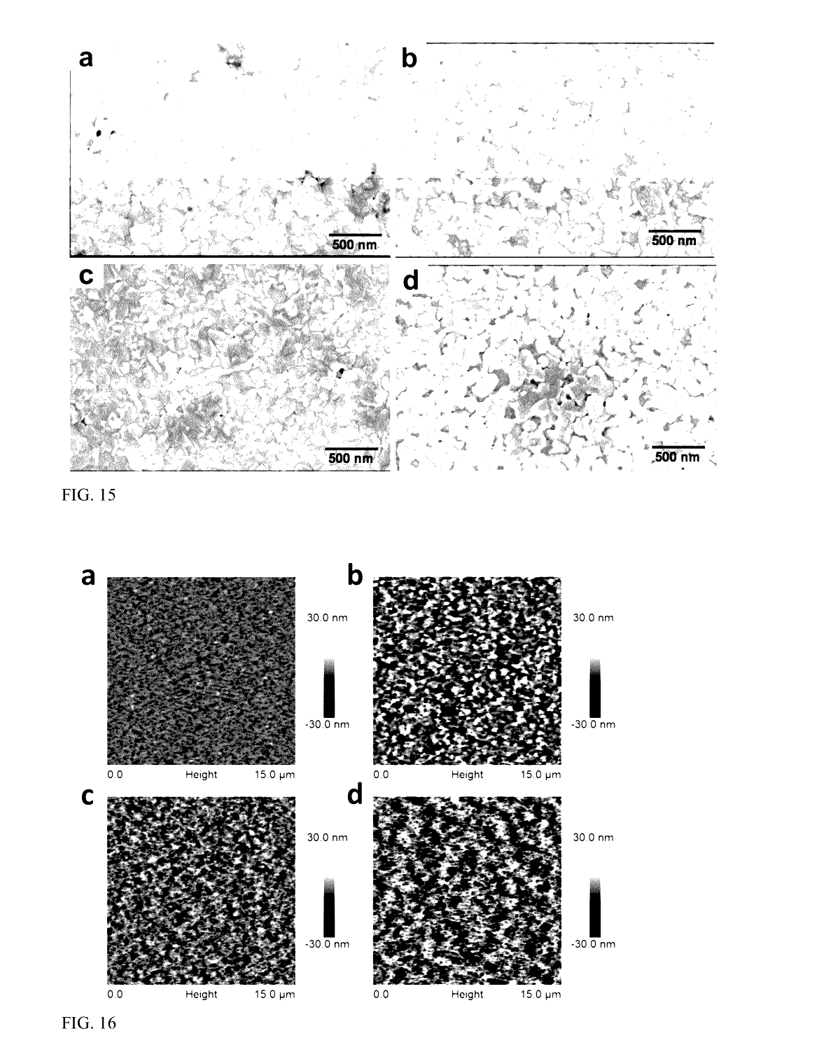

The preparation of thin and high quality perovskite films hinges on rapid crystal growth that was recently explored by Snaith et al. who reported that the use of lead (II) acetate (Pb(OAc)₂) resulted in much faster crystal growth on mesoporous titanium dioxide coated substrates compared to commonly utilized lead halides as the perovskite precursor. See, e.g., W. Zhang, M. Saliba, D. T. Moore, S. K. Pathak, M. T. Hörantner, T. Stergiopoulos, S. D. Stranks, G. E. Eperon, J. A. Alexander-Webber, A. Abate, A. Sadhanala, S. Yao, Y. Chen, R. H. Friend, L. A. Estroff, U. Wiesner, H. J. Snaith, Nat. Commum. 2015, 6, 6142. To transfer this procedure to the fabrication of thin perovskite films (i.e., less than or equal to 200 nm) on ITO/PEDOT:PSS substrates, it was necessary to further increase crystal growth rate and decrease crystal size, which is critical for obtaining tightly packed, continuous and pinhole-free perovskite layers. Here, the perovskite layer was formed by spin-casting a solution of lead acetate (Pb(OAc)₂) and methylammonium iodide (MAI) (1:3 molar ratio) in N,N-dimethylformamide (DMF) onto an ITO/PEDOT:PSS substrate, followed by thermal annealing at 100° C. for 2 minutes. The substrates were pre-heated to 100° C. immediately prior to spin-coating, and during the coating process film darkening was noted, indicating the formation of perovskite crystals. Additionally, a fast spin-coating speed (6000 rpm) produced high quality uniform perovskite films with excellent reproducibility. By using this hot spin-coating technique and varying the concentration of the perovskite precursor solution, the layer thickness was tuned from 70 to 160 nanometers (nm). The thinner perovskite films (70 nm, 90 nm and 110 nm) had a transmittance exceeding 50% o for wavelengths greater than 600 nm (FIG. 14(a)), while the thicker film (160 nm) had lower transmittance (<40%) from 500 nm to 740 nm (FIG. 14(a)), indicating that thick perovskite films are unsuitable as front sub-cells in tandem photovoltaic devices. Powder X-ray diffraction (PXRD) (FIG. 14(b)) demonstrates the efficient conversion of the Pb(OAc)₂+MAI precursor into crystalline methylammonium lead triiodide (CH₃NH₃PbI₃) perovskite using this hot spin-coating method. The dashed-lines (from left to right) in the PXRD pattern indicate the (100), (111), (200), and (220) tetragonal perovskite peaks. See, e.g., C. C. Stoumpos, C. D. Malliakas, M. G. Kanatzidis, Inorg. Chem. 2013, 52, 9019. Scanning electron microscopy (SEM) and atomic force microscopy (AFM) were performed to investigate the surface profiles of the perovskite films with varying thickness. The SEM images (FIG. 14(c) and FIG. 15) show homogeneous and almost pinhole-free films, with grain sizes of approximately 100 nm and little influence of the perovskite film thickness (FIG. 15). Additionally, AFM (FIG. 14(d) and FIG. 16) confirmed the homogeneity of the surface and reveals a smooth (root mean square (RMS) roughness: R_{q}<10 nm) tightly packed surface across all perovskite film thicknesses studied. These results demonstrate that CH₃NH₃PbI₃ can be fabricated through a single step solution deposition approach to provide thin perovskite films with continuous coverage on ITO/PEDOT:PSS substrates. In addition, the tunability of the perovskite film thickness from 70 nm to 160 nm allows for a precise adjustment of transmission and ensures that photons are absorbed by the back sub-cell.

Several terms are used herein to describe the photovoltaic performance of various devices. The term fill factor (FF), as used herein, refers to the ratio of the maximum power (Vₘₚ×Jₘₚ) divided by the short-circuit current density (J_{sc}) and open-circuit voltage (V_{oc}) displayed among the light current density-voltage (J-V) characteristics of solar cells, which is reported as a percentage. The term short circuit current density (J_{sc}), as used herein, is the maximum current through the load under short-circuit conditions. The term open circuit voltage (V_{oc}), as used herein, is the maximum voltage obtainable at the load under open-circuit conditions. The term power conversion efficiency (PCE), as used herein, is the ratio of the electrical power output to the light power input (Pᵢₙ), defined as PCE=V_{oc}J_{sc}FFPᵢₙ⁻¹, which is reported as a percentage.

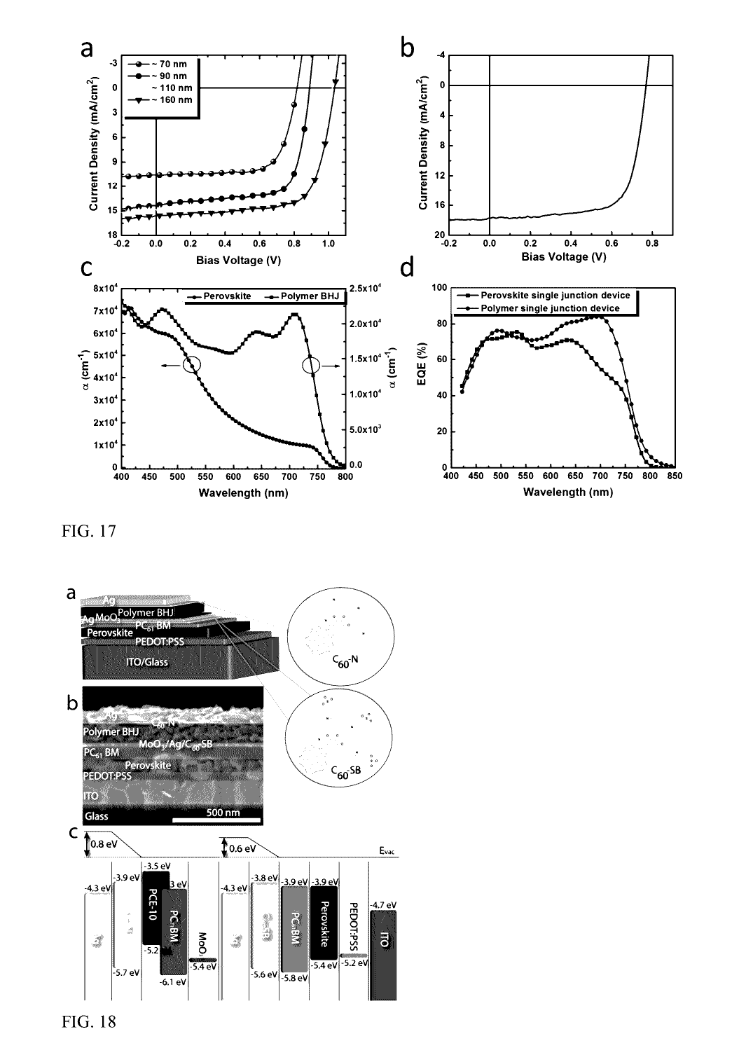

The photovoltaic properties of the perovskite thin films were first investigated using a single junction device architecture of ITO/PEDOT:PSS/perovskite/PC₆₁BM/C₆₀—N/Ag (PC₆₁BM: [6,6]-phenyl C₆₁-butyric acid methyl ester; C₆₀—N is the amine-functionalized fulleropyrrolidine shown in FIG. 18(a)). The thickness of the perovskite layer significantly influenced open-circuit voltage (V_{OC}) and short-circuit current density (J_{SC}), as shown in FIG. 17(a). Increasing the perovskite layer thickness from 70 nm to 160 nm raised the V_{OC} from 0.82 V to 1.03 V, and J_{SC} from 10.6 mA/cm² to 15.6 mA/cm² (FIG. 17(a)). Correspondingly, the maximum PCEs of these single junction perovskite devices were improved from 6.12% to 11.42%.

The photovoltaic performance of the optimal perovskite single junction devices with varying perovskite thicknesses is summarized in Table 2.

TABLE 2

| | Perovskite | Efficiency | | | |
|---|---|---|---|---|---|
| Sample | thickness | (%) | V_{OC} (V) | J_{SC} (mA/cm²) | FF (%) |
| 1 | 70 nm | 6.1 | 0.82 | 10.6 | 70.8 |
| 2 | 90 nm | 9.1 | 0.89 | 14.3 | 71.6 |
| 3 | 110 nm | 10.8 | 1.02 | 14.9 | 71.3 |
| 4 | 160 nm | 11.4 | 1.03 | 15.6 | 70.6 |

Single junction polymer-based solar cells were also fabricated and tested, using a low energy gap polymer:fullerene (PCE-10:PC₇₁BM) bulk heterojunction (BHJ) active layer, where the optimal layer thickness was identified as 100 nm. See, e.g., Z. He, B. Xiao, F. Liu, H. Wu, Y. Yang, S. Xiao, C. Wang, T. P. Russell, Y. Cao, Nat. Photon. 2015, 9, 174; Z. A. Page, Y. Liu, V. V. Duzhko, T. P. Russell, T. Emrick, Science 2014, 346, 441; H. Zhou, Y. Zhang, C.-K. Mai, S. D. Collins, G. C. Bazan, T.-Q. Nguyen, A. J. Heeger, Adv. Mater. 2015, 27, 1767. FIG. 17(b) shows the best performance for the single junction devices with an architecture of ITO/PEDOT:PSS/PCE-10:PC₇₁BM/C₆₀—N/Ag, resulting in a V_{OC} of 0.77 V, J_{SC} of 17.78 mA/cm², fill factor (FF) of 70.9% and maximum PCE of 9.68%. The strong UV-visible attenuation coefficients (α, cm⁻¹) (FIG. 17(c)) for perovskite and polymer BHJ films complement each other, leading to excellent absorption from 400-800 nm. External quantum efficiency (EQE) profiles of single junction devices (FIG. 17(d)) show that below 600 nm the perovskite single junction devices have a strong photo-response, while above 600 nm the photo-response of the polymer single junction device dominates, which corresponds well with the UV-visible absorption spectra.

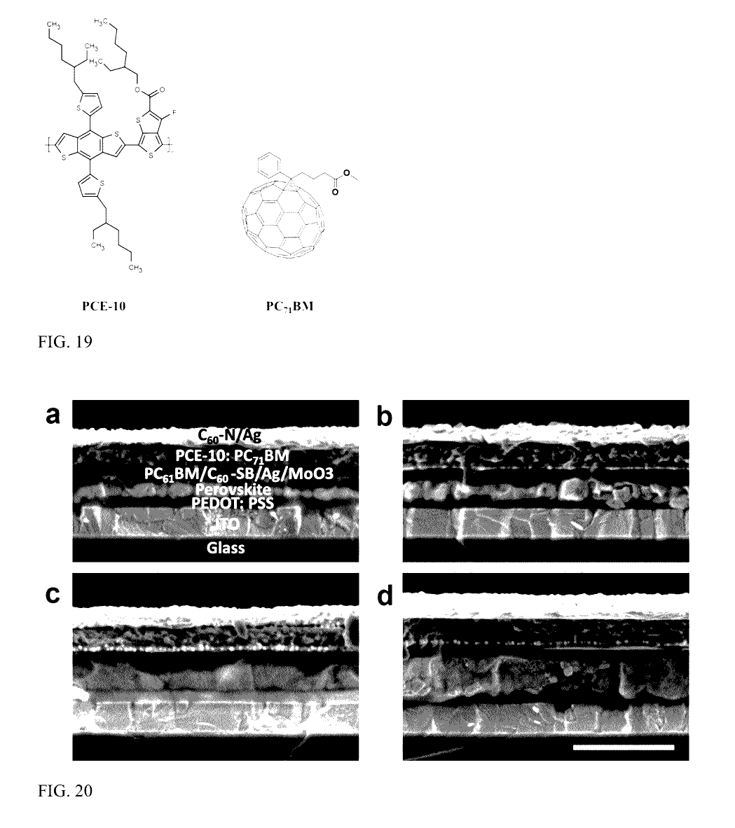

The tandem solar cell device architecture and composition is provided in FIG. 18(a). The front sub-cell is comprised of PC₆₁BM/perovskite planar heterojunction solar cell fabricated on an ITO/PEDOT:PSS substrate. The perovskite layer was prepared as for the single junction devices. The interconnecting layer on this sub-cell was a 30 nm film of tris(sulfobetaine)-substituted fulleropyrrolidine (C₆₀—SB) as an electron transport layer (ETL), 10 nm silver as a recombination layer, and 10 nm molybdenum trioxide (MoO₃) as a hole transport layer (HTL). The back sub-cell was comprised of a BHJ active layer (˜100 nm) containing a blend of [6,6]-phenyl C₇₁-butyric acid methyl ester (PC₇₁BM) as the acceptor and low bandgap conjugated polymer (PCE-10) as the donor. The chemical structures of PCE-10 polymer and PC₇IBM are shown in FIG. 19. This layer was coated onto the interconnecting layer, followed by C₆₀—N(15 nm) as an ETL and silver (100 nm) as metal cathode. C₆—SB was cast from 2,2,2-trifluoroethanol (TFE), while common solvents for polymer solar cell fabrication (chloroform, toluene, chlorobenzene and dichlorobenzene) neither removed the films nor modified their electronic signature. See, e.g., Y. Liu, Z. Page, S. Ferdous, F. Liu, P. Kim, T. Emrick, T. Russell, Adv. Energy Mater. 2015, 5, 1500405. The unique and orthogonal solubility of C₆₀—SB relative to PC₆₁BM makes it suitable for sequential solution processing, while providing robust protection for the front sub-cell, and an ideal platform for solution deposition of the polymer BHJ back sub-cell that is cast from chlorobenzene. Cross-sectional SEM (FIG. 18(b) and FIG. 20) allow for each layer of the device to be easily distinguished, with little-to-no interdiffusion between layers, attesting to the intrinsic orthogonal solubility of each material that enables fabrication of well-defined layers. SEM supports that the three-component interconnecting layer (C₆₀—SB/ultrathin Ag/MoO₃) effectively protects the perovskite front sub-cell and provides good contact between the two sub cells. FIG. 18(c) shows the energy band diagram of each material utilized in the device, highlighting the ability of both C₆₀—SB and C₆₀—N to generate large negative interfacial dipoles (Δ) on silver, as determined by ultraviolet photoelectron spectroscopy (UPS). See, e.g., Z. A. Page, Y. Liu, V. V. Duzhko, T. P. Russell, T. Emrick, Science 2014, 346, 441.

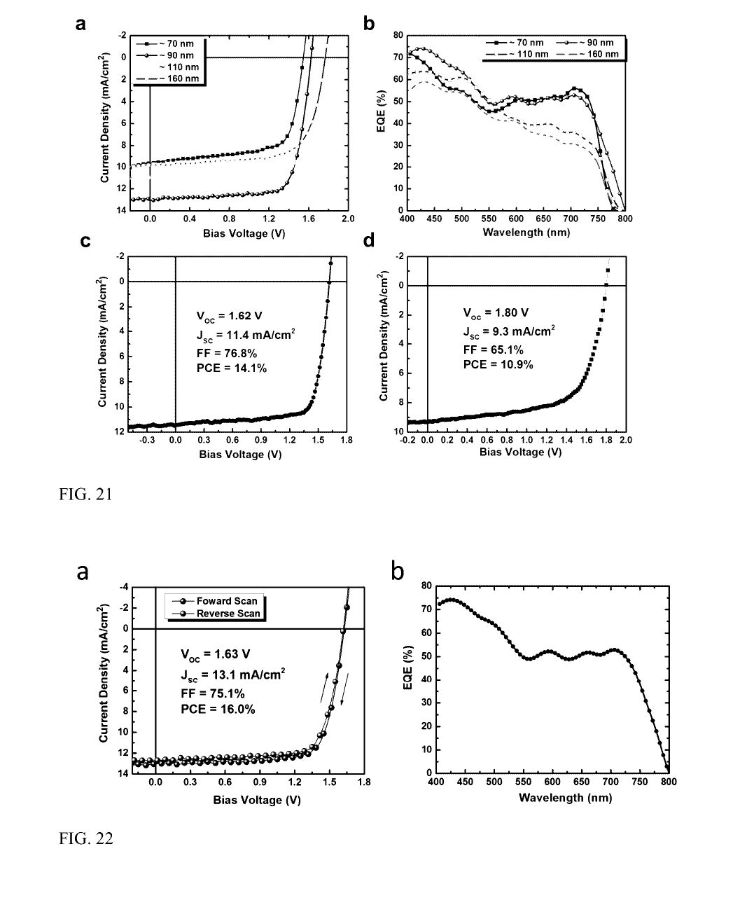

Given the demonstrated effect of perovskite thickness on V_{OC}, J_{SC}, and FF for the single junction devices, it was of interest to investigate how the thickness of a perovskite front sub-cell influenced the performance of tandem perovskite/polymer solar cells (FIG. 21). The photovoltaic performance of tandem perovskite/polymer devices with different perovskite layer thicknesses is summarized in Table 3.

TABLE 3

| | Perovskite | Efficiency | | | |
|---|---|---|---|---|---|
| Sample | thickness | (%) | V_{OC} (V) | J_{SC} (mA/cm²) | FF (%) |
| 5 | 70 nm | 10.3 | 1.55 | 9.7 | 68.9 |
| 6 | 90 nm | 15.9 | 1.62 | 12.9 | 76.1 |
| 7 | 110 nm | 14.1 | 1.76 | 11.0 | 72.9 |
| 8 | 160 nm | 12.0 | 1.77 | 9.9 | 69.1 |

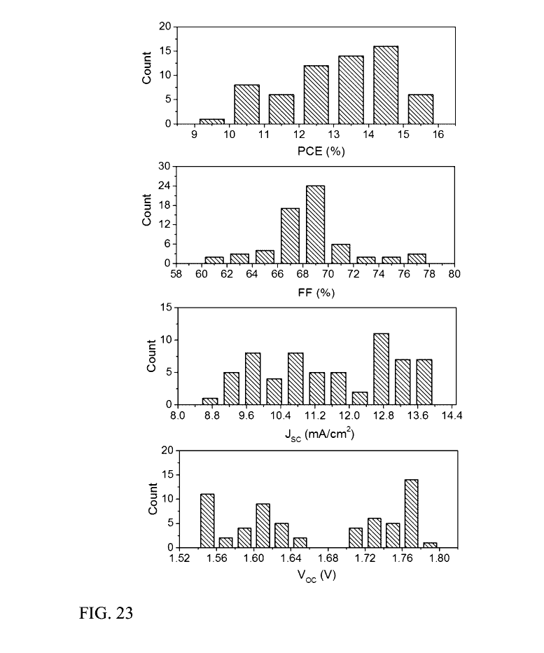

In all tandem solar cells, the polymer-containing BHJ layer thickness was kept constant at 100 nm, which was the optimized film thickness for single junction devices. Thinner perovskite layers (e.g., less than or equal to 110 nm) afford a higher J_{SC} relative to thicker layers, which is attributed to an enhanced transmittance (FIG. 14(a)), allowing for improved absorption of the polymer back sub-cell. EQE confirms an increased photo-response in the range where PCE-10 absorbs most strongly (600 nm-740 nm) (FIG. 21(b)) when thinner perovskite layers (e.g., less than or equal to 110 nm) were used in the tandem devices. Increasing the perovskite thickness beyond 110 nm results in a decrease in J_{SC} of the tandem devices, opposite the trend observed for single-junction perovskite solar cells. FIG. 22 (a) shows the current density-voltage (J-V) curve of the champion tandem device along with its lack of hysteresis. The corresponding EQE profile shown in FIG. 22 (b) gives a broad photo-response extending to 800 nm. A maximum PCE of 15.96% was achieved, representing a 40% and 65% improvement over the best corresponding single junction perovskite (PCE=11.42%) and polymer (PCE=9.68%) solar cells, respectively. Surprisingly, the highest FF (76.8%) achieved by this hybrid tandem device (FIG. 21(c)) even surpasses those of the perovskite and polymer single junction devices (FF=˜70%). Without wishing to be bound by theory, the large FF for the tandem devices is speculated to arise from efficient extraction of holes from the back sub-cell and electrons from the front sub-cell, due to the interconnection layers utilized, leading to successful recombination at the ultrathin Ag layer. In particular, the large negative Δ value generated on Ag by C₆₀—SB lowers the energy barrier for electron extraction from the perovskite front sub-cell. To confirm the viability of this protocol, 63 independent hybrid tandem devices were fabricated using 100 nm thick front and back sub-cells providing the majority of devices with high PCEs between 13% and 16% (FIG. 23). The presented methodology for the fabrication of tandem perovskite/polymer solar cells provides a platform to integrate state-of-the-art polymer BHJs with perovskite devices, since the pre-annealed perovskite front sub-cell has no influence on the polymer back sub-cell during the fabrication process. The FF value achieved by the hybrid tandem solar cells (maximum of 76.8%) is comparable to, or even better than, current perovskite/silicon hybrid systems, indicating an efficient union of the two sub cells by the three-component interconnecting layer.

The present inventors have therefore demonstrated a record efficiency to-date of a tandem perovskite/polymer solar cell fabricated from a facile solution deposition approach. The maximum efficiency of 16% achieved by this hybrid tandem device is 40% higher than the optimal perovskite and 65% o higher than the champion polymer single junction devices. AFM and SEM characterization confirm smooth and continuous thin perovskite layers, making the presented methodology an excellent platform for the preparation of tandem perovskite/polymer solar cells by solution deposition. The tandem solar cells described herein advantageously allow for the use of an ultrathin perovskite film while obtaining high efficiencies. This can reduce the amount of toxic lead included in a perovskite-containing solar cell, without sacrificing device performance. The present design demonstrates the synergy of these two previously competing materials when combined judiciously, paving the way for future development of high performance photovoltaic technology.

Experimental details follow.

Materials:

PbI₂ was used as received from Sigma Aldrich. Methyl ammonium iodide (MAI) was either used as received from 1-Material or synthesized by the following procedure: A solution of methylamine (24 milliliters, 33% in ethanol) was diluted with 100 milliliters of 180 proof ethanol. Then, concentrated hydroiodic acid (HI) (5 milliliters, 57% in water) was added dropwise to the methylamine solution. The reaction was stirred for 1 hour, and was dried in vacuo, which resulted in a yellow solid. The impure product was washed several times with diethyl ether and then recrystallized from a mixture of ethanol and diethyl ether. The final product was dried in vacuo to obtain a white solid, which was characterized using proton nuclear magnetic resonance (¹H NMR) spectroscopy (FIG. 11). Formamadinium iodide (FAI) was synthesized by dropwise addition of 12 milliliters of hydroiodic acid (57% in water) to 2.73 grams of formamidine acetate. Then the reaction mixture was stirred for 5 hours at 50° C. The solution was concentrated in vacuo to obtain a yellow solid. The impure product was washed several times with diethyl ether and then recrystallized from ethanol. The final product was dried in vacuo to obtain a white solid, which was characterized using ¹H NMR spectroscopy (FIG. 12). PCE-10 was purchased from 1-Material. Both PC₇₁BM and PC₆₁BM were purchased from Nano-C. All the solvents and lead acetate used in the examples were purchased from Sigma Aldrich and used without further purification

### Synthesis of 2,3,4-tris(3-(dimethylamino)propoxy)benzaldehyde

A 2-neck, 250 milliliter roundbottom flask equipped with a magnetic stir bar, inlet adapter, addition funnel and septa was flushed with nitrogen, followed by addition of 2,3,4-trihydroxybenzaldehyde (2.00 grams, 13.0 millimoles), 3-dimethylaminopropan-1-ol (4.55 grams, 44.1 millimoles), triphenylphosphine (11.57 grams, 44.1 millimoles) and tetrahydrofuran (THF) (anhydrous, 45 milliliters). The mixture was cooled to 0° C. with an ice bath while stirring under nitrogen. Diisopropyl azodicarboxylate was added to the addition funnel, dissolved in THF (anhydrous, 15 milliliters) and added dropwise to the reaction mixture. After complete addition the flask was removed from the ice bath and stirred at room temperature for five hours. The reaction was concentrated and the resulting crude mixture was washed with hexanes:diethyl ether (Hex:Et₂O; 1:1), filtering off the white phosphine-oxide byproduct through Celite. The filtrate was concentrated, dissolved in DCM and washed with 1 molar (M) hydrochloric acid (HCl_{aq}) (50 milliliters, 3×). The aqueous fractions were combined and washed with DCM until the organic phase no longer contained a UV-active compound (tested on UV-active thin layer chromatography plates (TLC) plates under short-wave 254 nm light). The acidic aqueous layer was neutralized with sodium carbonate (sat., aq.) and the 2,3,4-tris(3-(dimethylamino)propoxy)benzaldehyde product was extracted into dichloromethane (DCM). The combined organic phases were dried with MgSO₄ (anhydrous), filtered and concentrated to obtain a brown oil. The crude product was further purified using basic alumina (activated Brockman 1) eluting with DCM:MeOH:TEA (98:1:1) yielding 2,3,4-tris(3-(dimethylamino)propoxy)benzaldehyde (once concentrated) a light yellow oil (3.88 grams, 73%). ¹H NMR (700 MHz, Chloroform-d) δ 10.20 (s, 1H), 7.52 (d, J=8.8 Hz, 1H), 6.70 (d, J=8.8 Hz, 1H), 4.18 (t, J=6.5 Hz, 2H), 4.06 (t, J=6.5 Hz, 2H), 4.00 (t, J=6.5 Hz, 2H), 2.55-2.35 (m, 6H), 2.33-2.01 (m, 18H), 1.97 (p, J=6.8 Hz, 2H), 1.91 (ddt, J=12.9, 8.5, 6.3 Hz, 4H). ¹³C NMR (176 MHz, Chloroform-d) δ 189.05, 158.98, 156.47, 140.94, 123.99, 123.58, 108.37, 73.58, 72.09, 67.28, 56.66, 56.44, 56.26, 45.63, 45.61, 45.59, 28.62, 28.54, 27.51.

### Synthesis of 2,3,4-tris(3-(dimethylamino)propoxy)fulleropyrrolidine (C₆₀—N)

A 1-neck, 250 milliliter round-bottom flask equipped with a magnetic stir bar, inlet adapter, and Vigreux column was flushed with nitrogen, followed by addition of 2,3,4-tris(3-(dimethylamino)propoxy)benzaldehyde (300 milligrams, 0.73 millimoles), fullerene-C₆₀ (792 milligrams, 1.10 millimoles), sarcosine (200 milligrams, 2.2 millimoles) and 1,2-dichlorobenzene (110 milliliters). The mixture was degassed with nitrogen and then heated to reflux for 1 hour. The reaction was concentrated, dissolved in chloroform and filtered. The resulting filtrate was concentrated and then dissolved in carbon disulfide (CS₂). The crude mixture was added to silica gel, wet packed with hexanes, and eluted with CS₂, followed by CH2Cl2:TEA:MeOH (95:5:5). The first brown band that eluted was collected and concentrated, dissolved in chloroform, filtered through a 1 μm PTFE filter and precipitated into acetone. The precipitate was washed with acetone and dried to obtain the desired product as a brown solid (374 milligrams, 44%). ¹H NMR (300 MHz, Chloroform-d) δ 7.61 (d, J=8.8 Hz, 1H), 6.78 (d, J=8.8 Hz, 1H), 5.37 (s, 1H), 4.97 (d, J=9.3 Hz, 1H), 4.26 (d, J=9.4 Hz, 1H), 4.16 (t, J=6.2 Hz, 2H), 4.09-3.99 (m, 2H), 3.94 (t, J=6.5 Hz, 2H), 2.78 (s, 3H), 2.58-2.46 (m, 4H), 2.45-2.37 (m, 2H), 2.31 (s, 6H), 2.26 (s, 6H), 2.21 (s, 6H), 2.07-1.91 (m, 4H), 1.87-1.75 (m, 2H). ¹³C NMR (176 MHz, Chloroform-d) δ 156.85, 155.05, 154.31, 154.19, 152.98, 152.58, 147.40, 147.06, 146.83, 146.42, 146.36, 146.35, 146.29, 146.23, 146.18, 146.17, 146.05, 146.04, 145.85, 145.67, 145.64, 145.42, 145.40, 145.37, 145.35, 145.24, 145.20, 144.71, 144.70, 144.54, 144.46, 143.19, 143.10, 142.74, 142.73, 142.67, 142.64, 142.40, 142.38, 142.27, 142.26, 142.22, 142.17, 142.09, 141.97, 141.80, 141.79, 141.72, 141.33, 140.26, 140.21, 139.62, 139.60, 136.69, 136.58, 136.07, 134.97, 124.56, 122.77, 108.92, 76.36, 72.23, 71.77, 70.03, 67.08, 56.98, 56.75, 56.62, 45.87, 45.70, 45.66, 40.23, 28.93, 28.39, 27.81. MALDI-TOF (m/z): [M+H]+ calculated for: C₈₄H₄₅N₄O₃: 1157.34. found: 1157.60.

### Synthesis of 2,3,4-tris(3-(propylsulfobetaine)propoxy)fulleropyrrolidine

A 1-neck, 15 mL round-bottom flask equipped with a magnetic stir bar, inlet adapter, condenser and septum was flushed with nitrogen, followed by addition of 2,3,4-tris(3-(dimethylamino)propoxy)benzaldehyde (250 milligrams, 0.22 millimoles), 1,3-propanesultone (250 milligrams, 2.05 millimoles), Na₂CO₃ (70 milligrams, 0.65 millimoles) and TFE (5 milliliters). The reaction was heated to reflux while stirring for 24 hours, then cooled to room temperature. The product was precipitated into THF, filtered and washed with THF, followed by re-dissolving into TFE (5 milliliters), centrifuging and filtering through a 1 μm PTFE syringe filter into a dialysis membrane (1 kilodalton (kDa) molecular weight cutoff). The contents of the dialysis bag were dialyzed against pure water in a 4 liter beaker for 24 hours (changing the water five times) and then the water was removed by lyophilization. The product was obtained as a pure light brown fluffy solid (286 milligrams, 87%). ¹H NMR (700 MHz, 2,2,2,-Trifluoroethanol-d) δ 7.90 (br, 1H), 6.99 (br, 1H), 5.32 (br, 1H), 5.05 (br, 1H), 4.42-4.24 (m, 3H), 4.24-4.15 (m, 2H), 4.11-4.00 (m, 2H), 3.69-3.58 (m, 3H), 3.58-3.40 (m, 9H), 3.14 (br, 6H), 3.12-2.99 (m, 12H), 2.99-2.90 (m, 6H), 2.80 (br, 3H), 2.32 (br, 4H), 2.23 (br, 6H), 2.14 (br, 2H). MALDI-TOF (m/z): [M+H]+calculated for: C₉₃H₆₃N₄O₁₂S₃: 1524.36. found: 1524.19.

Inverted Device Fabrication:

The indium tin oxide (ITO)-coated glass substrates (20±5 ohms/square) were obtained from Thin Film Devices Inc., and were cleaned through ultrasonic treatment in detergent, deionized water, acetone, and isopropyl alcohol and then dried in an oven for 6 hours. Lead tri-halide based planar heterojunction perovskite solar cells were fabricated by sequential deposition method. PEDOT:PSS as HTL was spin coated on pre-cleaned ITO substrates at 2500 rpm for 40 s and annealed at 150° C. for 30 min. PbI₂ was dissolved in N,N-dimethylformamide (DMF) (400 mg/mL) and stirred for 30 min at 60° C. Hot solution of PbI₂ was then spin coated on pre-heated (85° C.) PEDOT:PSS-coated ITO substrates at 6000 rpm for 35 seconds and dried at 85° C. for 45 minutes. MAI and FAI (1:1 by weight) were dissolved in isopropanol (IPA) (40 mg/mL) and spin coated on PbI₂ film at 6000 rpm for 35 seconds. As-cast films were then annealed in dark at 85° C. for 45 minutes in air. A thin layer of PC₆₁BM (60-70 nm) as ETL was then spin coated inside a glove box (N₂ atmosphere, <1 ppm O₂, <1 ppm H₂O) from a solution in chlorobenzene (20 mg/mL) at 1000 rpm for 60 s. For the devices with interlayer, C₆₀—N in TFE (3 mg/mL) was spin coated onto PC₆₁BM surface with a thickness of about 10 nm. Finally, 100 nm Ag cathode was deposited (area 6 mm² defined by metal shadow mask) on the active layer under high vacuum (1×10⁻⁶ mbar) using a thermal evaporator.

Tandem Device Fabrication.

The indium tin oxide (ITO)-coated glass substrates (20±5 ohms/square) were obtained from Thin Film Devices Inc., and were cleaned through ultrasonic treatment in detergent, deionized water, acetone, and isopropyl alcohol and then dried in an oven for 6 hours. PEDOT:PSS as hole transport layer was spin coated on pre-cleaned ITO substrates at 2500 rpm for 40 s and annealed at 150° C. for 30 min. The perovskites were prepared by spin-coating a perovskite precursor in DMF onto the hot PEDOT: PSS/ITO substrates (100° C.) at a spin-speed of 6000 rpm for 60 seconds inside a glove box (N₂ atmosphere, <1 ppm O₂, <1 ppm H₂O). As-cast films were then annealed in dark at 100° C. for 2 min in glove box. To achieve perovskite with different film thickness, we prepared perovskite precursor solution with a concentration of 600 milligrams/milliliters (mg/mL), 450 mg/mL, 300 mg/mL and 200 mg/mL, respectively. The corresponding perovskite film thickness was 160 nm, 110 nm, 90 nm, and 70 nm as determined by profilometry. For perovskite single junction devices, after the preparation of perovskite film, a thin layer of PC₆₁BM (60-70 nm) as ETL was then spin coated inside a glove box (N₂ atmosphere, <1 ppm O₂, <1 ppm H₂O) from a solution in chlorobenzene (20 mg/mL) at 1000 rpm for 60 seconds. Then C₆₀—N in TFE (3 mg/mL) was spin coated onto PC₆BM surface with a thickness of ˜10 nm. Finally, 100 nm Ag cathode was deposited (area 6 mm² defined by metal shadow mask) on the active layer under high vacuum (1×10⁻⁶ mbar) using a thermal evaporator. For polymer single junction devices, a mixture of PCE-10 and PC₇IBM (1:1.8 weight ratio) in chlorobenzene:1,8-diiodoocatane (DIO) (3 volume percent DIO) was stirred at 55° C. for 1 day. The photoactive layers were deposited by spin-coating the solution onto the PEDOT:PSS/ITO substrates. The thickness of the active layer film was 100 nm (determined by profilometry). DIO was removed under vacuum, followed by spin-coating of C₆₀—N(15 nm). 100 nm Ag cathode was deposited (area 6 mm² defined by metal shadow mask) on the active layer under high vacuum (1×10⁶ mbar) using a thermal evaporator. For tandem perovskite/polymer devices, after the preparation of perovskite film, a thin layer of PC₆₁BM (60 nm-70 nm) was then spin coated from chlorobenzene. Then C₆₀—SB in TFE (6 mg/mL) was spin coated onto PC₆₁BM surface with a thickness of ˜30 nm. 10 nm silver and 10 nm molybdenum trioxide (MoO₃) were deposited onto C₆₀—SB film sequentially by thermal evaporation. The polymer BHJ layer (100 nm) was spin-coated onto the bottom layer. DIO was removed under vacuum, followed by spin-coating of C₆₀—N(15 nm). 100 nm Ag cathode was deposited (area 6 mm² defined by metal shadow mask) on the active layer under high vacuum (1×10⁻⁶ mbar) using a thermal evaporator.

Solar-Cell Characterization.

The current-voltage (I-V) characteristics of the devices were measured under simulated AM1.5G irradiation (100 mWcm⁻²) using a Xe lamp-based Newport 91160 300-W Solar Simulator. A Xe lamp equipped with an AM1.5G filter was used as the white light source. A QEPVSI Measurement Kit (obtained from Newport Corporation/Oriel Instruments) with 150 watt Xe arc lamp, monochromator and calibrated silicon reference cell with power meter was used for quantum efficiency (QE)/Incident Photon to Charge Carrier Efficiency (IPCE) measurement for solar cells over a 400-1100 nm spectral range in DC mode. The light intensity was adjusted with an NREL-calibrated silicon (Si) solar cell with a KG-5 filter. To avoid overestimating the photocurrent, each device was isolated completely by scratching the surrounding films around the device using a steel blade, and a metal photo mask with an aperture area of 5.5 mm² was used during device measurement.

UV-Visible Spectroscopy:

The absorptions of perovskite film and polymer film on glass/PEDOT:PSS substrates were measured on Shimadzu UV 3600. Attenuation coefficients were determined by casting three relatively thick films (polymer BHJ: ˜160 nm; perovskite film: ˜330 nm) onto glass/PEDOT:PSS substrates, measuring their absorption profiles with UV-Vis absorption spectroscopy, determining thickness using profilometry and taking the average values from both measurements as A (absorption, AU) and 1 (path length, cm) to determine the attenuation coefficient (α, cm-1) using the Beer-Lambert law for films: α=A/l.

PXRD:

Powder X-Ray diffraction (PXRD) was performed on a PANalytic X'Pert3 X-Ray diffractometer with a Ni filter, ½″ diverging slit, vertical goniometer, and X'Celerator detector. Measurements were made from 2θ=5°-60° under Cu K-Alpha (1.542 Å).

AFM:

Atomic force microscopy was performed on a Digital Instruments Dimension 3100, operating in tapping mode.

SEM:

Scanning electron microscopy (SEM) and cross-sectional SEM was performed on a FEI Magellan 400 FESEM.

KPFM Measurements:

Samples were prepared for KPFM by evaporating 70 nm of Ag on a cleaned Si wafer. Then a 3 mg/mL solution of PC₆BM in chloroform or C₆₀—N in TFE was spin coated on top of the Ag electrode. Typical film thicknesses were about 10 nm. For as-prepared device samples, Scotch® tape was stuck to the Ag electrode of devices prepared as mentioned above, and the electrode is carefully peeled off and secured ‘tape-up’ on a glass slide so that the underside of the Ag electrode is available for KPFM measurements. KPFM measurements were made in air using an Asylum Research MFP3D-stand-alone AFM. The probes (ANSCM-PT) used were Pt/Ir coated (˜25 nm) Si probes with a spring constant of 1-5 N/m as supplied from AppNano. Scans were typically 2.5 μm×0.625 μm (512 pixel×128 pixel) at a scan speed of 0.5 Hz. The nap mode lift height (Δz) was 30 nm for all scans. It was required to ground the Si wafer to instrument ground in order to measure a force curve to approach the sample and make measurements; therefore only changes in V_{CPD} were reported and not absolute work functions. It was not required to ground exfoliated Ag electrode samples. The same probe was used for all measurements, and the Φ_{probe} is assumed to remain constant. Analysis of potential maps was done in the Asylum Research MFP3D software in Igor Pro.

The perovskite solar cells, methods of making, and devices comprising the perovskite solar cells include at least the following non-limiting embodiments.

### Embodiment 1

An inverted perovskite solar cell comprising, an anode substrate; a photoactive layer comprising a perovskite; a hole transport layer disposed between the anode substrate and the photoactive layer: an electron transport layer disposed on the photoactive layer; a metal cathode layer; and an interlayer disposed between the electron transport layer and the metal cathode layer, wherein the interlayer comprises a fulleropyrrolidine having structure (I), wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group.

### Embodiment 2

The inverted perovskite solar cell of embodiment 1, wherein the anode substrate comprises indium tin oxide.

### Embodiment 3

The inverted perovskite solar cell of embodiments 1 or 2, wherein the hole transport layer comprises poly(ethylenedioxythiophene) and polystyrene sulfonate.

### Embodiment 4

The inverted perovskite solar cell of any of embodiments 1 to 3, wherein the perovskite comprises a first perovskite material having structure (II)

CₙH₂ₙ₊₁NH₃XY₃ (II)

wherein n is independently at each occurrence an integer from 1 to 9; X is independently at each occurrence lead, tin, or germanium; and Y is independently at each occurrence iodide, bromide, or chloride; and a second perovskite material having structure (III)

H₂NCHNH₂XY₃ (III)

wherein X is independently at each occurrence lead, tin, or germanium; and Y is independently at each occurrence iodide, bromide, or chloride.

### Embodiment 5

The inverted perovskite solar cell of embodiment 4, wherein n is 1; X is lead; and Y is iodide.

### Embodiment 6

The inverted perovskite solar cell of embodiment 4 or 5, wherein the first and second perovskite materials are present in a weight ratio of 1:1.

### Embodiment 7

The inverted perovskite solar cell of any of embodiments 1 to 6, wherein the electron transport layer comprises C₆₀, (6,6)-phenyl-C₇₁ butyric acid methyl ester, (6,6)-phenyl-C₆₁ butyric acid methyl ester, or a combination thereof.

### Embodiment 8

The inverted perovskite solar cell of any of embodiments 1 to 7, wherein the metal cathode layer comprises silver.

### Embodiment 9

The inverted perovskite solar cell of any of embodiments 1 to 8, wherein the interlayer comprises the fulleropyrrolidine of structure (I), wherein R¹ is a divalent C₁₋₁₂ alkylene group, and each occurrence of R² and R³ are hydrogen.

### Embodiment 10

The perovskite solar cell of any of embodiments 1 to 8, wherein the interlayer comprises the fulleropyrrolidine of structure (I), wherein R¹ is a divalent C₁₋₁₂ alkylene group, R² is a C₁₋₁₂ alkyl group, and R³ is hydrogen.

### Embodiment 11

The inverted perovskite solar cell of any of embodiments 1 to 8, wherein the interlayer comprises the fulleropyrrolidine of structure (I), wherein R¹ is a divalent C₁₋₁₂ alkylene group, and each occurrence of R² and R³ is a C₁₋₁₂ alkyl group.

### Embodiment 12

The inverted perovskite solar cell of any of embodiments 1 to 11, wherein R¹ is a propylene group.

### Embodiment 13

The inverted perovskite solar cell of any of embodiments 1 to 8, wherein the interlayer comprises the fulleropyrrolidine of structure (I), wherein R¹ is a divalent propylene group, and each occurrence of R² and R³ is a methyl group.

### Embodiment 14

The inverted perovskite solar cell of any of embodiments 1 to 13, wherein the interlayer has a thickness of 1 to 100 nanometers.

### Embodiment 15

The inverted perovskite solar cell of any of embodiments 1 to 14, wherein the photoactive layer has a thickness of 100 to 500 nanometers.

### Embodiment 16

An inverted perovskite solar cell comprising, an anode substrate comprising indium tin oxide; a photoactive layer comprising a perovskite; a hole transport layer disposed between the anode substrate and the photoactive layer; an electron transport layer comprising fullerene or a derivative thereof disposed on the photoactive layer; a metal cathode layer comprising silver; and an interlayer disposed between the electron transport layer and the metal cathode layer, wherein the interlayer comprises a fulleropyrrolidine having structure (IV).

### Embodiment 17

The inverted perovskite solar cell of any of embodiments 1 to 16, wherein the perovskite solar cell exhibits a power conversion efficiency of at least 10%.

### Embodiment 18

The inverted perovskite solar cell of any of embodiments 1 to 17, wherein the perovskite solar cell exhibits a power conversion efficiency that is at least 50% greater than a perovskite solar cell not including the interlayer comprising a fulleropyrrolidine.

### Embodiment 19

The inverted perovskite solar cell of any of embodiments 1 to 18, wherein the perovskite solar cell exhibits a power conversion efficiency after storing in air for up to two months that is 0 to 50% less than the initial power conversion efficiency of the perovskite solar cell.

### Embodiment 20

A device comprising the perovskite solar cell of any of embodiments 1 to 19.

### Embodiment 21

A tandem solar cell comprising, a first sub-cell comprising a perovskite layer having a thickness of 50 to 200 nanometers; a second sub-cell comprising a photoactive layer and an interlayer disposed on the photoactive layer, wherein the interlayer comprises a first fulleropyrrolidine having structure (I), wherein R¹ is independently at each occurrence a divalent C₁₋₁₂ alkylene group, a C₆₋₃₀ arylene or heteroarylene group, or an alkylene oxide group; and R² and R³ are independently at each occurrence a hydrogen or a C₁₋₁₂ alkyl group; and an interconnecting layer disposed between the first sub-cell and the second sub-cell, wherein the interconnecting layer comprises a second fulleropyrrolidine having structure (V), wherein L is independently at each occurrence a divalent C₁₋₁₆ alkylene group, C₆₋₃₀ arylene or heteroarylene group, or alkylene oxide group; and R⁴ is independently at each occurrence a zwitterion having the structure -A-B—X; wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero.

### Embodiment 22

The tandem solar cell of embodiment 21, wherein the first sub-cell comprises: an anode substrate; the perovskite layer; a first hole transport layer disposed between the anode substrate and the perovskite layer; and a first electron transport layer disposed on the perovskite layer.

### Embodiment 23

The tandem solar cell of embodiment 21 or 22, wherein the second sub-cell comprises: a metal cathode layer; the photoactive layer; and the interlayer disposed between the photoactive layer and the metal cathode layer.

### Embodiment 24

The tandem solar cell of any one of embodiments 21 to 23, wherein the interconnecting layer comprises a second hole transport layer; a metal recombination layer disposed on the second hole transport layer; and a second electron transport layer disposed on the metal recombination layer on a side opposite the second hole transport layer, the second electron transport layer comprising the second fulleropyrrolidine having structure (II).

### Embodiment 25

The tandem solar cell of embodiment 24, wherein the first electron transport layer of the first sub-cell is in contact with at least a portion of the second electron transport layer of the interconnecting layer and the photoactive layer of second sub-cell is in contact with at least a portion of the second hole transport layer of the interconnecting layer.

### Embodiment 26

The tandem solar cell of any one of embodiments 22 to 25, wherein the anode substrate comprises indium tin oxide.

### Embodiment 27

The tandem solar cell of any one of embodiments 22 to 26, wherein the first hole transport layer comprises poly(ethylenedioxythiophene) and polystyrene sulfonate.

### Embodiment 28

The tandem solar cell of any one of embodiments 21 to 27, wherein the perovskite comprises a perovskite material having structure (II)

CₙH₂ₙ₊₁NH₃XY₃ (II)

wherein n is an integer from 1 to 9; X is lead, tin, or germanium; and Y is independently at each occurrence iodide, bromide, or chloride.

### Embodiment 29

The tandem solar cell of embodiment 28, wherein n is 1; X is lead; and Y is iodide.

### Embodiment 30

The tandem solar cell of any one of embodiments 22 to 29, wherein the first electron transport layer comprises fullerene or a derivative thereof.

### Embodiment 31

The tandem solar cell of any one of embodiments 22 to 30, wherein the first electron transport layer comprises C₆₀, (6,6)-phenyl-C₇₁ butyric acid methyl ester, (6,6)-phenyl-C₆₁ butyric acid methyl ester, or a combination thereof

### Embodiment 32

The tandem solar cell of any one of embodiments 23 to 31, wherein the photoactive layer comprises an electron-donating material comprising poly(3-hexylthiophene), poly(p-phenylenevinylene), poly[2-methoxy-5-(3,7-dimethyloctyloxy)-1,4-phenylene vinylene], poly(2-methoxy-5-(2′-ethyl-hexyloxy)-1,4-phenylene vinylene), poly(2,7-(9-(2′-ethylhexyl)-9-hexyl-fluorene)-alt-5, 5-(4′,7′-di-2-thienyl-2′,1′,3′-benzothiadiazole)), poly(2,6-(4,4-bis-(2-ethylhexyl)-4H-cyclopenta(2,1-b;3,4-b′)dithiophene)-alt-4,7-(2,1,3-benzothiadiazole)), poly(p-phenylene-ethynylene)-alt-poly(p-phenylene-vinylene), poly((2,7-(9-(2′-ethylhexyl)-9-hexyl-fluorene)-alt-5, 5-(4′,7′-di-2-thienyl-2′,1′,3′-benzothiadiazole))-co-(2,7-(9-(2′-ethylhexyl)-9-hexyl-fluorene)-alt-2,5-thiophene)), poly(4,8-bis-alkyloxybenzo(1,2-b:4,5-b′)dithiophene-2,6-diyl-alt-(alkylthieno(3,4-b)thiophene-2-(2-ethyl-1-hexanone)-2,6-diyl)), poly(4,8-bis-alkyloxybenzo(1,2-b:4, 5-b′)dithiophene-2,6-diyl-alt-(thieno(3,4-b)thiophene-2-carboxylate)-2,6-diyl), poly(N-9′-heptadecanyl-2, 7-carbazole-alt-5,5-(4′,7′-di-2-thienyl-2′,1′,3′-benzothiadiazole)), poly[4,8-bis[(2-ethylhexyl) oxy]benzo[1,2-b:4,5-b′]dithiophene-2,6-diyl][3-fluoro-2-[(2-ethylhexyl)carbonyl]′ thieno[3,4-b]thiophenediyl], poly [(4,4′-bis(2-ethylhexyl)dithienol [3,2-b:2′,3′-d]silole)-2,6-diyl-alt-(2,1,3-benzothiadiazole)-4,7-diyl], poly [4, 8-bis(5-(2-ethylhexyl)thiophen-2-yl)benzo[1,2-b;4, 5-b′]dithiophene-2,6-diyl-alt-(4-(2-ethylhexyl)-3-fluorothieno[3,4-b]thiophene-)-2-carboxylate-2-6-diyl)], or a combination thereof; and an electron-accepting material comprising (6,6)-phenyl-C₇₁ butyric acid methyl ester, (6,6)-phenyl-C₆₁ butyric acid methyl ester, or a combination thereof.

### Embodiment 33

The tandem solar cell of any one of embodiments 23 to 32, wherein the metal cathode layer comprises silver.

### Embodiment 34

The tandem solar cell of any one of embodiments 24 to 33, wherein the second hole transport layer comprises molybdenum oxide.

### Embodiment 35

The tandem solar cell of any one of embodiments 24 to 34, wherein the metal recombination layer comprises silver.

### Embodiment 36

The tandem solar cell of any one of embodiments 21 to 35, wherein R¹ is a divalent 1,3-propylene group, and each occurrence of R² and R³ is a methyl group.

### Embodiment 37

The tandem solar cell of any one of embodiments 21 to 36, wherein each occurrence of L is a propylene group; and each occurrence of R⁴ is a sulfobetaine zwitterion having structure (VI), wherein R⁵ is independently at each occurrence a substituted or unsubstituted C₁₋₁₂ alkyl group; and p is independently at each occurrence an integer from 1 to 12.

### Embodiment 38

A tandem solar cell comprising, a first sub-cell comprising: an anode substrate; a perovskite layer having a thickness of 50 to 200 nanometers; a first hole transport layer disposed between the anode substrate and the perovskite layer; and a first electron transport layer comprising fullerene or a derivative thereof disposed on the perovskite layer; a second sub-cell comprising: a photoactive layer; a metal cathode layer, and an interlayer disposed between the photoactive layer and the metal cathode layer, wherein the interlayer comprises a first fulleropyrrolidine having structure (I), wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group; and an interconnecting layer disposed between the electron transport layer of the first sub-cell and the photoactive layer of the second sub-cell, wherein the interconnecting layer comprises: a second hole transport layer; a metal recombination layer disposed on the second hole transport layer; and a second electron transport layer disposed on the metal recombination layer on a side opposite the second hole transport layer, the second electron transport layer comprising a second fulleropyrrolidine having structure (V), wherein L is independently at each occurrence a divalent C₁₋₁₆ alkylene group, C₆₋₃₀ arylene or heteroarylene group, or alkylene oxide group; and R⁴ is independently at each occurrence a zwitterion having the structure -A-B—X; wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero; and wherein the first electron transport layer of the first sub-cell is in contact with at least a portion of the second electron transport layer of the interconnecting layer and the photoactive layer of second sub-cell is in contact with at least a portion of the second hole transport layer of the interconnecting layer.

### Embodiment 39

A method of making a tandem solar cell, the method comprising, forming a first hole transport layer on an anode substrate; forming a perovskite layer on the first hole transport layer, wherein forming the perovskite layer comprises: coating a perovskite precursor solution on the first hole transport layer at a temperature of 70 to 120° C. to form a perovskite precursor film disposed on the first hole transport layer; and annealing the perovskite precursor film to provide the perovskite layer; forming a first electron transport layer on the perovskite layer; forming a second electron transport layer on the first electron transport layer, the second electron transport layer comprising a second fulleropyrrolidine having structure (V), wherein L is independently at each occurrence a divalent C₁₋₁₆ alkylene group, C₆₋₃₀ arylene or heteroarylene group, or alkylene oxide group; and R⁴ is independently at each occurrence a zwitterion having the structure -A-B—X; wherein A is a center of permanent positive charge or a center of permanent negative charge; B is a divalent group comprising a C₁₋₁₂ alkylene group, a C₆₋₃₀ arylene or heteroarylene group, or an alkylene oxide group; and X is a center of permanent positive charge or a center of permanent negative charge, provided that the zwitterion has an overall net charge of zero; forming a metal recombination layer on the second electron transport layer; forming a second hole transport layer on the metal recombination layer; forming a photoactive layer on the second hole transport layer; forming an interlayer on the photoactive layer, wherein the interlayer comprises a first fulleropyrrolidine having structure (I), wherein R¹ is independently at each occurrence a divalent C₁₋₁₂ alkylene group, a C₆₋₃₀ arylene or heteroarylene group, or an alkylene oxide group; R² is independently at each occurrence a hydrogen or a C₁₋₁₂ alkyl group; and R³ is independently at each occurrence a hydrogen or a C₁₋₁₂ alkyl group; and forming a metal cathode layer on the interlayer to provide the tandem solar cell.

### Embodiment 40

The method of embodiment 39, wherein forming the first hole transport layer, the perovskite layer, the first electron transport layer, the second electron transport layer, the photoactive layer, and the interlayer comprises solution coating the layers; and forming the metal recombination layer, the second hole transport layer, and the metal cathode layer comprises thermally evaporating the layers.

### Embodiment 41

A device comprising the tandem solar cell of any one of embodiments 21 to 38, wherein the tandem solar cell is a power source for the device.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

All cited patents, patent applications, and other references are incorporated herein by reference in their entirety, including priority applications U.S. Patent Application No. 62,252,026, filed Nov. 6, 2015, and U.S. Patent Application No. 62/255,055, filed Nov. 13, 2015. However, if a term in the present application contradicts or conflicts with a term in the incorporated reference, the term from the present application takes precedence over the conflicting term from the incorporated reference.

All ranges disclosed herein are inclusive of the endpoints, and the endpoints are independently combinable with each other. Each range disclosed herein constitutes a disclosure of any point or sub-range lying within the disclosed range. The use of the terms “a” and “an” and “the” and similar referents in the context of describing the invention (especially in the context of the following claims) are to be construed to cover both the singular and the plural, unless otherwise indicated herein or clearly contradicted by context. “Or” means “and/or” unless clearly indicated otherwise. Further, it should further be noted that the terms “first,” “second,” and the like herein do not denote any order, quantity, or importance, but rather are used to distinguish one element from another. The modifier “about” used in connection with a quantity is inclusive of the stated value and has the meaning dictated by the context (e.g., it includes the degree of error associated with measurement of the particular quantity).

As used herein, the term “alkyl” means a branched or straight chain, saturated, monovalent hydrocarbon group, e.g., methyl, ethyl, i-propyl, and n-butyl. “Alkylene” means a straight or branched chain, saturated, divalent hydrocarbon group (e.g., methylene (—CH₂—) or propylene (—(CH₂)₃—)). “Alkenyl” and “alkenylene” mean a monovalent or divalent, respectively, straight or branched chain hydrocarbon group having at least one carbon-carbon double bond (e.g., ethenyl (—HC═CH₂) or propenylene (—HC(CH₃)═CH₂—). “Alkynyl” means a straight or branched chain, monovalent hydrocarbon group having at least one carbon-carbon triple bond (e.g., ethynyl). “Alkoxy” means an alkyl group linked via an oxygen (i.e., alkyl-O—), for example methoxy, ethoxy, and sec-butyloxy. “Cycloalkyl” and “cycloalkylene” mean a monovalent and divalent cyclic hydrocarbon group, respectively, of the formula —CₙH₂ₙ₋ₓ and —CₙH₂ₙ₋ₓ— wherein x is the number of cyclization(s). “Aryl” means a monovalent, monocyclic or polycyclic aromatic group (e.g., phenyl or naphthyl). “Arylene” means a divalent, monocyclic or polycyclic aromatic group (e.g., phenylene or naphthylene). The prefix “halo” means a group or compound including one more halogen (F, Cl, Br, or I) substituents, which can be the same or different. The prefix “hetero” means a group or compound that includes at least one ring member that is a heteroatom (e.g., 1, 2, or 3 heteroatoms, wherein each heteroatom is independently N, O, S, or P.

“Substituted” means that the compound or group is substituted with at least one (e.g., 1, 2, 3, or 4) substituents instead of hydrogen, where each substituent is independently nitro (—NO₂), cyano (—CN), hydroxy (—OH), halogen, thiol (—SH), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl, C₇₋₁₃ arylalkylene (e.g, benzyl), C₇₋₁₂ alkylarylene (e.g, toluyl), C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—), provided that the substituted atom's normal valence is not exceeded, and that the substitution does not significantly adversely affect the manufacture, stability, or desired property of the compound. When a compound is substituted, the indicated number of carbon atoms is the total number of carbon atoms in the group, including those of the substituent(s).

1. An inverted perovskite solar cell comprising,
an anode substrate;
a photoactive layer comprising a perovskite;
a hole transport layer disposed between the anode substrate and the photoactive layer;
an electron transport layer disposed on the photoactive layer;
a metal cathode layer; and
an interlayer disposed between the electron transport layer and the metal cathode layer, wherein the interlayer comprises a fulleropyrrolidine having structure (I) 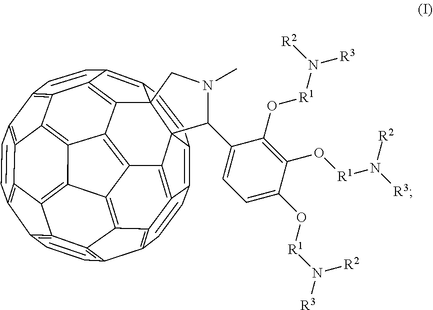
wherein
R¹ is independently at each occurrence a divalent C₁₋₁₂ alkylene group, a C₆₋₃₀ arylene or heteroarylene group, or an alkylene oxide group;
R² is independently at each occurrence a hydrogen or a C₁₋₁₂ alkyl group; and
R³ is independently at each occurrence a hydrogen or a C₁₋₁₂ alkyl group.

2. The inverted perovskite solar cell of claim 1, wherein
the anode substrate comprises indium tin oxide;
the hole transport layer comprises poly(ethylenedioxythiophene) and polystyrene sulfonate;
the electron transport layer comprises C₆₀, (6,6)-phenyl-C₇₁ butyric acid methyl ester, (6,6)-phenyl-C₆₁ butyric acid methyl ester, or a combination thereof; and
the metal cathode layer comprises silver.

3. The inverted perovskite solar cell of claim 1, wherein the perovskite comprises
a first perovskite material having structure (II)
CₙH₂ₙ₊₁NH₃XY₃ (II)
wherein
n is independently at each occurrence an integer from 1 to 9;
X is independently at each occurrence lead, tin, or germanium; and
Y is independently at each occurrence iodide, bromide, or chloride; and
a second perovskite material having structure (III)
H₂NCHNH₂XY₃ (III)
wherein
X is independently at each occurrence lead, tin, or germanium; and
Y is independently at each occurrence iodide, bromide, or chloride.

4. The inverted perovskite solar cell of claim 3, wherein
n is 1;
X is lead; and
Y is iodide.

5. The inverted perovskite solar cell of claim 3, wherein the first and second perovskite materials are present in a weight ratio of 1:1.

6. The inverted perovskite solar cell of claim 1, wherein the interlayer comprises the fulleropyrrolidine of structure (I), wherein R¹ is a divalent C₁₋₁₂ alkylene group, and each occurrence of R² and R³ are hydrogen.

7. The perovskite solar cell of claim 1, wherein the interlayer comprises the fulleropyrrolidine of structure (I), wherein R¹ is a divalent C₁₋₁₂ alkylene group, R² is a C₁₋₁₂ alkyl group, and R³ is hydrogen.

8. The inverted perovskite solar cell of claim 1, wherein the interlayer comprises the fulleropyrrolidine of structure (I), wherein R¹ is a divalent C₁₋₁₂ alkylene group, and each occurrence of R² and R³ is a C₁₋₁₂ alkyl group.

9. The inverted perovskite solar cell of claim 1, wherein the interlayer comprises the fulleropyrrolidine of structure (I), wherein R¹ is a divalent propylene group, and each occurrence of R² and R³ is a methyl group.

10. The inverted perovskite solar cell of claim 1, wherein the interlayer has a thickness of 1 to 100 nanometers and the photoactive layer has a thickness of 100 to 500 nanometers.

11. The inverted perovskite solar cell of claim 1, wherein the perovskite solar cell exhibits one or more of
a power conversion efficiency of at least 10%;
a power conversion efficiency that is at least 50% greater than a perovskite solar cell not including the interlayer comprising a fulleropyrrolidine; and
a power conversion efficiency after storing in air for up to two months that is 0 to 50% less than the initial power conversion efficiency of the perovskite solar cell.

12. A tandem solar cell comprising,
a first sub-cell comprising a perovskite layer having a thickness of 50 to 200 nanometers;
a second sub-cell comprising a photoactive layer and an interlayer disposed on the photoactive layer, wherein the interlayer comprises a first fulleropyrrolidine having structure (I) 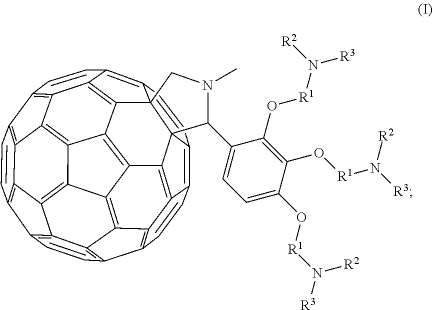
wherein
R¹ is independently at each occurrence a divalent C₁₋₁₂ alkylene group, a C₆₋₃₀ arylene or heteroarylene group, or an alkylene oxide group; and
R² and R³ are independently at each occurrence a hydrogen or a C₁₋₁₂ alkyl group; and
an interconnecting layer disposed between the first sub-cell and the second sub-cell, wherein the interconnecting layer comprises a second fulleropyrrolidine having structure (V) 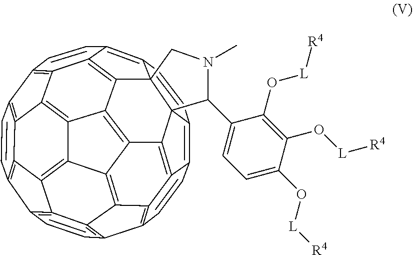
wherein
L is independently at each occurrence a divalent C₁₋₁₆ alkylene group, C₆₋₃₀ arylene or heteroarylene group, or alkylene oxide group; and
R⁴ is independently at each occurrence a zwitterion having the structure -A-B—X;
wherein
A is a center of permanent positive charge or a center of permanent negative charge;
B is a divalent group comprising a C₁₋₁₂ alkylene group, a C₆₋₃₀ arylene or heteroarylene group, or an alkylene oxide group; and
X is a center of permanent positive charge or a center of permanent negative charge, provided that the zwitterion has an overall net charge of zero.

13. The tandem solar cell of claim 12, wherein
the first sub-cell comprises:
an anode substrate;
the perovskite layer;
a first hole transport layer disposed between the anode substrate and the perovskite layer; and
a first electron transport layer disposed on the perovskite layer; and
the second sub-cell comprises:
a metal cathode layer;
the photoactive layer; and
the interlayer disposed between the photoactive layer and the metal cathode layer.

14. The tandem solar cell of claim 12, wherein the interconnecting layer comprises
a second hole transport layer;
a metal recombination layer disposed on the second hole transport layer; and
a second electron transport layer disposed on the metal recombination layer on a side opposite the second hole transport layer, the second electron transport layer comprising the second fulleropyrrolidine having structure (V);
wherein the first electron transport layer of the first sub-cell is in contact with at least a portion of the second electron transport layer of the interconnecting layer and the photoactive layer of second sub-cell is in contact with at least a portion of the second hole transport layer of the interconnecting layer.

15. The tandem solar cell of claim 13, wherein
the anode substrate comprises indium tin oxide;
the first hole transport layer comprises poly(ethylenedioxythiophene) and polystyrene sulfonate;
the first electron transport layer comprises fullerene or a derivative thereof; and
the metal cathode layer comprises silver.

16. The tandem solar cell of claim 12, wherein the perovskite comprises
a perovskite material having structure (II)
CₙH₂ₙ₊₁NH₃XY₃ (II)
wherein
n is an integer from 1 to 9,
X is lead, tin, or germanium; and
Y is independently at each occurrence iodide, bromide, or chloride.

17. The tandem solar cell of claim 16, wherein
n is 1;
X is lead; and
Y is iodide.

18. The tandem solar cell of claim 13, wherein the photoactive layer comprises
an electron-donating material comprising poly(3-hexylthiophene), poly(p-phenylenevinylene), poly[2-methoxy-5-(3,7-dimethyloctyloxy)-1,4-phenylene vinylene], poly(2-methoxy-5-(2′-ethyl-hexyloxy)-1,4-phenylene vinylene), poly(2,7-(9-(2′-ethylhexyl)-9-hexyl-fluorene)-alt-5,5-(4′,7′-di-2-thienyl-2′,1′,3′-benzothiadiazole)), poly(2,6-(4,4-bis-(2-ethylhexyl)-4H-cyclopenta(2,1-b;3,4-b′)dithiophene)-alt-4,7-(2,1,3-benzothiadiazole)), poly(p-phenylene-ethynylene)-alt-poly(p-phenylene-vinylene), poly((2,7-(9-(2′-ethylhexyl)-9-hexyl-fluorene)-alt-5,5-(4′,7′-di-2-thienyl-2′,1′,3′-benzothiadiazole))-co-(2,7-(9-(2′-ethylhexyl)-9-hexyl-fluorene)-alt-2,5-thiophene)), poly(4,8-bis-alkyloxybenzo(1,2-b:4,5-b′)dithiophene-2,6-diyl-alt-(alkylthieno(3,4-b)thiophene-2-(2-ethyl-1-hexanone)-2,6-diyl)), poly(4,8-bis-alkyloxybenzo(1,2-b:4, 5-b′)dithiophene-2,6-diyl-alt-(thieno(3,4-b)thiophene-2-carboxylate)-2,6-diyl), poly(N-9′-heptadecanyl-2,7-carbazole-alt-5,5-(4′,7′-di-2-thienyl-2′,1′,3′-benzothiadiazole)), poly[4,8-bis[(2-ethylhexyl) oxy]benzo[1,2-b:4,5-b′]dithiophene-2,6-diyl][3-fluoro-2-[(2-ethylhexyl)carbonyl]′ thieno[3,4-b]thiophenediyl], poly [(4,4′-bis(2-ethylhexyl)dithienol [3,2-b:2′,3′-d]silole)-2,6-diyl-alt-(2,1,3-benzothiadiazole)-4,7-diyl], poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)], or a combination thereof; and
an electron-accepting material comprising (6,6)-phenyl-C71 butyric acid methyl ester, (6,6)-phenyl-C₆₁ butyric acid methyl ester, or a combination thereof.

19. The tandem solar cell of claim 14, wherein the second hole transport layer comprises molybdenum oxide and the metal recombination layer comprises silver.

20. The tandem solar cell of claim 12, wherein
R¹ is a divalent 1,3-propylene group;
each occurrence of R² and R³ is a methyl group;
each occurrence of L is a propylene group; and
each occurrence of R⁴ is a sulfobetaine zwitterion having structure (VI) 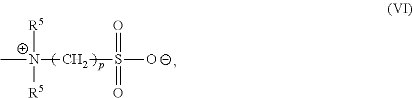
wherein
R⁵ is independently at each occurrence a substituted or unsubstituted C₁₋₁₂ alkyl group; and
p is independently at each occurrence an integer from 1 to 12.
